(19) United States
(12) Patent Application Publication
(10) Pub. No.: US 2026/0319364 A1
(43) Pub. Date: Oct. 15, 2026

(54) RESIN COMPOSITION, MODIFIED RESIN COMPOSITION, AND METHOD FOR PRODUCING MODIFIED RESIN COMPOSITION

(71) Applicant: Resonac Corporation, Tokyo (JP)

(72) Inventors: Eri IDA, Tokyo (JP); Tomomitsu WAKABAYASHI, Tokyo (JP); Tsukasa HARA, Tokyo (JP)

(73) Assignee: Resonac Corporation, Tokyo (JP)

(21) Appl. No.: 19/491,454

(22) PCT Filed: Apr. 1, 2024
(86) PCT No.: PCT/JP2024/013400

§ 371 Date: Dec. 9, 2025

(30) Foreign Application Priority Data
Jul. 13, 2023 (JP) 2023-115345

(51) Int. Cl. G03F 7/038; C08F 8/00; C08J 3/24

(52) U.S. Cl. CPC G03F 7/0388; C08F 8/00; C08J 3/24; C08F 2810/20; C08J 2333/02; C08J 2333/08; C08J 2333/14

(57) ABSTRACT

Provided is a resin composition containing a copolymer (A), a basic catalyst (B), and a solvent (C), wherein the copolymer (A) contains a structural unit (a) having an acid group and a structural unit (pb) having a group represented by formula (1) (In formula (1), R¹ and R⁴ each independently are a hydrogen atom or a C1-20 hydrocarbon group, R² and R³ each independently are a hydrogen atom or a C1-20 hydrocarbon group, and * represents a linking site with a residue obtained by removing the group of formula (1) from the structural unit (pb)), and the basic catalyst (B) has a pKa (acidity constant) at 25° C. of 4-12.

### TECHNICAL FIELD

The contents of the present disclosure relate to a resin composition, a modified resin composition, a photosensitive resin composition, a photosensitive coloring composition, a cured resin film, an image display element, a method for producing a resin composition, and a method for producing a modified resin composition.

### BACKGROUND ART

In recent years, from the viewpoint of resource conservation and energy conservation, photosensitive resin compositions that can be cured by active energy rays, such as ultraviolet rays and electron rays, have been widely used in the fields of various coatings, printing, paints, adhesives and the like. In the field of electronic materials such as printed circuit substrates as well, photosensitive resin compositions that can be cured by active energy rays have been used for solder resists, color filter resists, and the like. The required properties for curable photosensitive resin compositions have become increasingly diverse and highly advanced, and among these, there is a need for short-time curability in consideration of productivity and low-temperature curability for suppressing thermal damage to members to be applied.

Color filters generally include a transparent substrate, such as a glass substrate, red (R), green (G) and blue (B) pixels formed on the transparent substrate, a black matrix formed at the boundary of the pixels, and a protective film formed on the pixels and the black matrix. A color filter having such a configuration is usually produced by sequentially forming a black matrix, pixels, and a protective film on a transparent substrate. As methods for forming pixels and black matrices (hereinafter, pixels and black matrices are referred to as “colored patterns”), various methods have been proposed. Among these, the pigment/dye dispersion method, in which a photosensitive resin composition is used as a resist and a colored pattern is fabricated by photolithography in which coating, exposure, development and baking are repeated, affords a colored pattern, which is excellent in durability and has few defects such as pin holes, and is thus currently the mainstream method.

In general, the photosensitive resin composition used in the photolithography contains an alkali-soluble resin, a reactive diluent, a photopolymerization initiator, a coloring agent and a solvent. The pigment/dye dispersion method has the above advantages, but often has problems that the photosensitive resin composition is required to exhibit high heat resistance, and the kind of usable coloring agent is limited to coloring agents, which can withstand high baking temperatures, since baking is repeated to form the black matrices and R, G, and B patterns.

In recent years, there has been proposed a photosensitive resin composition that exhibits low-temperature curability and is also compatible with members exhibiting low heat resistance, such as organic EL. For example, PTL 1 discloses a coloring composition having a specific partial structure and a hydroxyl group as a photosensitive resin composition that can afford a cured product excellent in solvent resistance under low-temperature curing conditions as well and can be suitably used in applications such as color filters.

### CITATION LIST

### Patent Literature

PTL 1: Japanese Patent Application Publication No. 2021-102759

### SUMMARY OF INVENTION

### Technical Problem

However, in recent years, still more low-temperature curability is required, and accordingly, curing of the film is not sufficiently performed, and there is a concern that solvent resistance decreases because of the trade-off relation. Hence, in curing under low temperature conditions as well, it is required that the cured product fabricated exhibits high solvent resistance. In addition to this, it is also required that the photosensitive resin composition exhibits excellent developability.

The present disclosure provides a resin composition capable of efficiently introducing an ethylenically unsaturated group into a resin. The present disclosure further provides a modified resin composition that contributes to improvement in developability and affords a cured resin film exhibiting excellent solvent resistance, and a photosensitive resin composition and a photosensitive coloring composition that are obtained using the modified resin composition. The present disclosure further provides a cured resin film exhibiting excellent solvent resistance, and an image display element including the cured resin film.

### Solution to Problem

The present disclosure includes the following aspects.

[1]

A resin composition comprising: a copolymer (A);
a basic catalyst (B); and
a solvent (C),
wherein
the copolymer (A) is a copolymer comprising:
a structural unit (a) having an acid group; and
a structural unit (pb) having a group represented by the following Formula (1), and
the basic catalyst (B) is a basic catalyst having a pKa (acidity constant) of 4 to 12 at 25° C.;

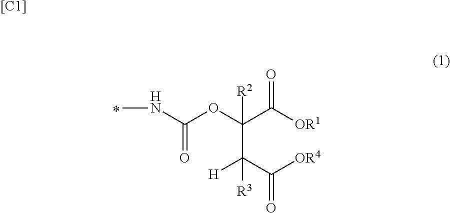

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)).
   [2]

A modified resin composition comprising: a modified copolymer (A2);
a basic catalyst (B); and
a solvent (C),
wherein
the modified copolymer (A2) comprises:
a structural unit (a) having an acid group;
a structural unit (pb) having a group represented by the following Formula (1); and
a structural unit (b) having a group represented by the following Formula (1-1) or (1-2),
and
the basic catalyst (B) is a basic catalyst having a pKa (acidity constant) of 4 to 12 at 25° C.;

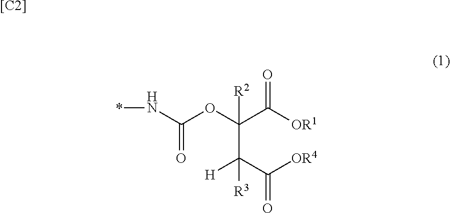

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)),

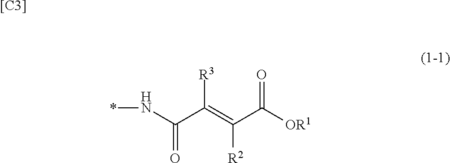

(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b)), and

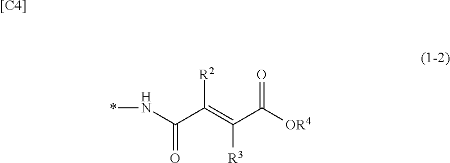

(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b)).
   [3]

The modified resin composition according to aspect [2], wherein the basic catalyst (B) is at least one selected from the group consisting of pyridine, a pyridine derivative, and an imidazole compound.

[4]

The modified resin composition according to aspect [2] or [3], wherein the basic catalyst (B) is at least one selected from pyridine, 4-dimethylaminopyridine, 1,2-dimethylimidazole, triethylamine, and 1,4-diazabicyclo[2.2.2]octane.

[5]

The modified resin composition according to any one of aspects [2] to [4], wherein the modified copolymer (A2) has an ethylenically unsaturated group equivalent of 300 to 10,000 g/mol.

[6]

A photosensitive resin composition comprising: the modified resin composition according to any one of aspects [2] to [5];
a reactive diluent (D); and
a photopolymerization initiator (E).
   [7]

A photosensitive coloring composition comprising: the modified resin composition according to any one of aspects [2] to [5];
a reactive diluent (D);
a photopolymerization initiator (E); and
a coloring agent (F).
   [8]

A cured resin film comprising a cured product of the photosensitive resin composition according to aspect [6].

[9]

A cured resin film comprising a cured product of the photosensitive coloring composition according to aspect [7].

[10]

A color filter comprising a colored pattern comprising a cured product of the photosensitive coloring composition according to aspect [7].

[11]

An image display element comprising the color filter according to aspect [10].

[12]

A method for producing a resin composition, the method comprising: a step (I) of preparing the resin composition comprising a copolymer (A), a basic catalyst (B), and a solvent (C), wherein
the copolymer (A) is a copolymer comprising:
a structural unit (a) having an acid group; and
a structural unit (pb) having a group represented by the following Formula (1),
and
the basic catalyst (B) is a basic catalyst having a pKa (acidity constant) of 4 to 12 at 25° C.;

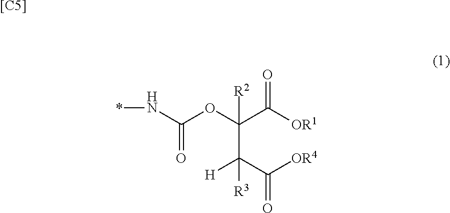

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)).
   [13]

A method for producing a modified resin composition, the method comprising: a heating step (II) of maintaining the resin composition obtained by the production method according to aspect [12] at 50° C. to 100° C. for 30 to 300 minutes, wherein
in the heating step (II), the copolymer (A) is converted to a modified copolymer (A2),
the modified copolymer (A2) comprises:
a structural unit (a) having an acid group;
a structural unit (pb) having a group represented by the following Formula (1); and
a structural unit (b) having a group represented by the following Formula (1-1) or (1-2):

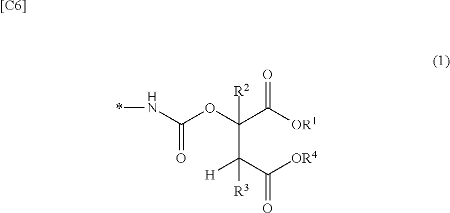

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)),

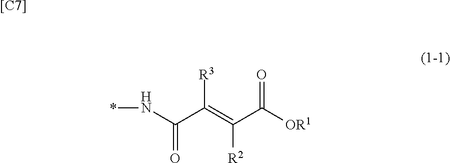

(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b)), and

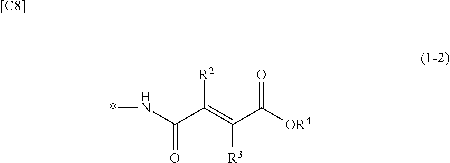

(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b)).

### Advantageous of Effects of Invention

According to the present disclosure, it is possible to provide a resin composition capable of efficiently introducing an ethylenically unsaturated group into a resin. Further, it is possible to provide a modified resin composition that contributes to improvement in developability and affords a cured resin film exhibiting excellent solvent resistance, and a photosensitive resin composition and a photosensitive coloring composition that are obtained using the modified resin composition. It is also possible to provide a cured resin film excellent in solvent resistance and a color filter, which are obtained by curing the photosensitive resin composition and photosensitive coloring composition, respectively, and an image display element including the cured resin film or the color filter.

### DESCRIPTION OF EMBODIMENTS

Hereinafter, embodiments of the present invention will be described in detail. However, the present invention is not limited to the following embodiments.

In the present specification, when “to” is used for a numerical range, the numerical values at both ends are an upper limit value and a lower limit value, respectively, and are included in the numerical range. When a plurality of upper limit values or lower limit values are listed, a numerical range can be created from all combinations of the upper limit values and the lower limit values. Similarly, when a plurality of numerical ranges are listed, the upper limit value and the lower limit value can be individually selected from these numerical ranges and combined to create separate numerical ranges.

In the present specification, the term “(meth)acrylic acid” refers to methacrylic acid or acrylic acid, the term “(meth)acrylate” refers to acrylate or methacrylate, the term “(meth)acryloyl” refers to acryloyl or methacryloyl, and the term “(meth)acryloyloxy” means acryloyloxy or methacryloyloxy.

In the present specification, the term “ethylenically unsaturated bond” refers to a double bond formed between carbon atoms except for carbon atoms forming an aromatic ring, and the term “ethylenically unsaturated group” refers to a group having an ethylenically unsaturated bond.

In the present specification, the term “structural unit” refers to a unit derived from a polymerizable compound used as a monomer or a unit obtained by further modifying a unit derived from a polymerizable compound used as a monomer.

### <Resin Composition>

A resin composition of an embodiment contains a copolymer (A), a basic catalyst (B), and a solvent (C).

### [Copolymer (A)]

The copolymer (A) does not contain a structural unit (b) described later but contains a structural unit (a) having an acid group and a structural unit (pb) having a group represented by the following Formula (1). Since the copolymer (A) has the structural unit (pb) having a group represented by the following Formula (1), the conversion to the structural unit (b) progresses by the action of the basic catalyst (B) described later, and an ethylenically unsaturated group is introduced into the copolymer (A). By using the copolymer (A) in the photosensitive resin composition, it is possible to improve the developability and obtain a cured resin film exhibiting favorable solvent resistance.

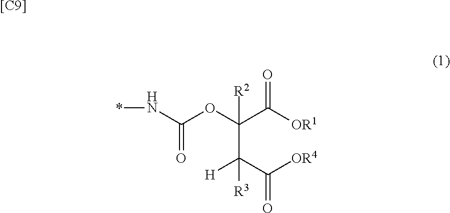

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb))

The copolymer (A) may further contain a structural unit (c) having a hydroxy group, a structural unit (d) having a blocked isocyanate group, or a combination thereof, if necessary. The copolymer (A) may further contain a structural unit (e) other than the structural units (a) to (d) and (pb), if necessary.

### (Structural Unit (a) Having Acid Group)

The structural unit (a) having an acid group (also simply referred to as “structural unit (a)”) is not particularly limited as long as it is a structural unit that does not have an ethylenically unsaturated group but has an acid group. As the copolymer (A) has the structural unit (a) having an acid group, in a case where a modified copolymer (A2) obtained by converting the copolymer (A) is used in the photosensitive resin composition, favorable alkali developability can be obtained. Examples of the acid group include a carboxy group, a sulfo group, and a phospho group. Among these acid groups, a carboxy group is preferred as the acid group of the structural unit (a) from the viewpoint of ease of availability.

The structural unit (a) having an acid group is preferably a structural unit derived from a monomer (m-a) having an acid group and an ethylenically unsaturated bond (hereinafter also simply referred to as monomer (m-a)). Specific examples of the monomer (m-a) include unsaturated carboxylic acids or anhydrides thereof, such as (meth)acrylic acid, α-bromo(meth)acrylic acid, β-furyl(meth)acrylic acid, crotonic acid, cinnamic acid, α-cyanocinnamic acid, maleic acid, maleic anhydride, monomethyl maleate, monoethyl maleate, monoisopropyl maleate, fumaric acid, itaconic acid, itaconic anhydride, citraconic acid, and citraconic anhydride; unsaturated sulfonic acids such as 2-acrylamido-2-methylpropanesulfonic acid, tert-butylacrylamidosulfonic acid, and p-styrenesulfonic acid; and unsaturated phosphonic acids such as vinylphosphonic acid. The monomer (m-a) is preferably an unsaturated carboxylic acid or an anhydride thereof, more preferably (meth)acrylic acid or a (meth)acrylate having a carboxylic acid group, and still more preferably (meth)acrylic acid.

The monomer (m-a) having an acid group and an ethylenically unsaturated bond may be used singly or in combination of two or more kinds thereof.

The content of the structural unit (a) is preferably 5 to 50 mol %, more preferably 8 to 40 mol %, and still more preferably 10 to 30 mol % in the total structural units of the copolymer (A). When the content of the structural unit (a) is 5 mol % or more, favorable developability of the photosensitive resin composition that is obtained using the modified copolymer (A2) obtained by converting the copolymer (A) can be obtained. When the content of the structural unit (a) is 50 mol % or less, the content of the structural unit (pb) can be sufficiently ensured, and thus the effect due to the structural unit (b) can be sufficiently ensured.

### (Structural Unit (pb) Having Group Represented by Formula (1))

The structural unit (pb) having a group represented by Formula (1) (also simply referred to as “structural unit (pb)”) is a structural unit that does not have an acid group or an ethylenically unsaturated group but has a group represented by the following Formula (1).

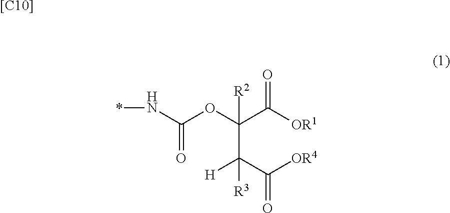

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb))

The group represented by Formula (1) does not have to be of one kind. R¹ in each structural unit may be different, R² in each structural unit may also be different, R³ in each structural unit may also be different, and R⁴ in each structural unit may also be different.

In Formula (1), R¹ and R⁴ are each independently a hydrogen atom or a hydrocarbon group having 1 to 20 carbon atoms, and preferably a hydrocarbon group having 1 to 5 carbon atoms. Particularly, it is more preferable that R¹ and R⁴ be each independently a hydrocarbon group having 1 to 3 carbon atoms since the conversion reaction from the structural unit (pb) to the structural unit (b) having a group represented by Formula (1-1) or (1-2) described later is likely to occur. R¹ and R⁴ are preferably an alkyl group having 1 to 5 carbon atoms, preferably a methyl group or an ethyl group, and particularly preferably an ethyl group. R¹ and R⁴ may be the same as or different from each other. R¹ and R⁴ are preferably the same since the monomer (m-pb) described later can be easily produced.

In Formula (1), R² and R³ are each independently a hydrogen atom or a hydrocarbon group having 1 to 20 carbon atoms, and preferably a hydrogen atom or a hydrocarbon group having 1 to 5 carbon atoms. In particular, since the conversion reaction from the structural unit (pb) to the structural unit (b) having a group represented by Formula (1-1) or (1-2) described later is likely to occur, R² and R³ are each independently more preferably a hydrogen atom or a methyl group, and particularly preferably a hydrogen atom. R² and R³ may be the same as or different from each other. R² and R³ are preferably the same since the monomer (m-pb) described later can be easily produced.

The structural unit (pb) is a structural unit derived from the monomer (m-pb) having a group represented by Formula (1) (also simply referred to as “monomer (m-pb)”). The monomer (m-pb) may be used singly or in combination of two or more kinds thereof.

The monomer (m-pb) is a monomer having an ethylenically unsaturated bond and the group represented by Formula (1).

Examples of the monomer (m-pb) include a compound obtained by subjecting an isocyanate group in an isocyanate compound having an ethylenically unsaturated group such as a vinyl group or a (meth)acryloyloxy group in the molecule to the urethanization reaction with a hydroxy group in a hydroxy group-containing compound represented by the following Formula (4).

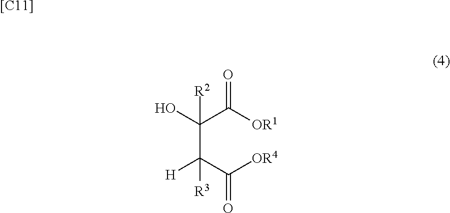

(In Formula (4), R¹, R², R³ and R⁴ are the same as R¹, R², R³ and R⁴ in Formula (1))

As a method for subjecting the isocyanate compound having an ethylenically unsaturated group to the urethanization reaction with a hydroxy group-containing compound represented by Formula (4), a known method can be used.

The urethanization reaction can be performed regardless of the presence or absence of a solvent. The solvent used in a case of performing the urethanization reaction using a solvent may be a solvent inert to an isocyanate group, and known solvents can be used.

The urethanization reaction is generally performed preferably at a temperature of −10° C. or more and 90° C. or less, more preferably at a temperature of 5° C. or more and 70° C. or less, and still more preferably at a temperature of 10° C. or more and 40° C. or less.

When the urethanization reaction is performed, a urethanization catalyst such as dibutyltin dilaurate, a polymerization inhibitor such as phenothiazine, hydroquinone monomethyl ether, or 2,6-di-tert-butyl-4-methylphenol (BHT), and the like may be used, if necessary.

Examples of the isocyanate compound having an ethylenically unsaturated group, which is used as a raw material for the monomer (m-pb), include an isocyanate compound represented by the following Formula (5).

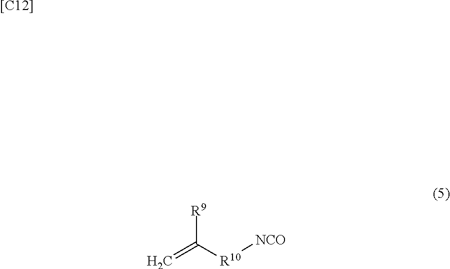

(In Formula (5), R⁹ is a hydrogen atom or a methyl group; R¹⁰ is —CO—, —COOR¹¹— (where R¹¹ is an alkylene group having 1 to 6 carbon atoms) or —COO—R¹²O—CONH—R¹³— (where R¹² is an alkylene group having 2 to 6 carbon atoms, and R¹³ is an alkylene group having 2 to 12 carbon atoms or an arylene group having 6 to 12 carbon atoms, which may have a substituent))

In the isocyanate compound represented by Formula (5), from the viewpoint of ease of preparation of the isocyanate compound, R¹⁰ is preferably —COOR¹¹—, and R¹¹ is more preferably an alkylene group having 1 to 4 carbon atoms.

Specific examples of the isocyanate compound represented by Formula (5) include 2-isocyanatoethyl (meth)acrylate, 2-isocyanatopropyl (meth)acrylate, 3-isocyanatopropyl (meth)acrylate, 2-isocyanato-1-methylethyl (meth)acrylate, 2-isocyanato-1,1-dimethylethyl (meth)acrylate, 4-isocyanatocyclohexyl (meth)acrylate, and methacryloyl isocyanate.

As the isocyanate compound used as a raw material for the monomer (m-pb), a reaction product obtained by reacting a hydroxyalkyl (meth)acrylate with a diisocyanate compound at an equimolar ratio (hydroxyalkyl (meth)acrylate:diisocyanate compound=1 mol:1 mol) may be used.

The alkyl group of the hydroxyalkyl (meth)acrylate is preferably an ethyl group or a n-propyl group, and more preferably an ethyl group from the viewpoint of simplicity of the reaction.

Examples of the diisocyanate compound include hexamethylene diisocyanate, 2,4-(or 2,6-)tolylene diisocyanate (TDI), 4,4′-diphenylmethane diisocyanate (MDI), 3,5,5-trimethyl-3-isocyanatomethylcyclohexyl isocyanate (IPDI), m-(or p-)xylene diisocyanate, 1,3-(or 1,4-)bis(isocyanatomethyl)cyclohexane, and lysine diisocyanate.

Examples of the other isocyanate compound used as a raw material for the monomer (m-pb) include 1,1-bis(methacryloyloxymethyl)methyl isocyanate, 1,1-bis(methacryloyloxymethyl)ethyl isocyanate, 1,1-bis(acryloyloxymethyl)methyl isocyanate, and 1,1-bis(acryloyloxymethyl)ethyl isocyanate.

From the viewpoint of low-temperature curability, the isocyanate compound used as a raw material for the monomer (m-pb) is preferably an isocyanate compound having a (meth)acryloyl group or a (meth)acryloyloxy group, more preferably an isocyanate group-containing (meth)acrylate, more preferably 2-isocyanatoethyl (meth)acrylate, 2-isocyanatopropyl (meth)acrylate, 3-isocyanatopropyl (meth)acrylate, 2-isocyanato-1-methylethyl (meth)acrylate, 1,1-bis(methacryloyloxymethyl)ethyl isocyanate, 2-isocyanato-1,1-dimethylethyl (meth)acrylate, 4-isocyanatocyclohexyl (meth)acrylate or methacryloyl isocyanate, and still more preferably 2-isocyanatoethyl (meth)acrylate, 2-isocyanatopropyl (meth)acrylate, or 1,1-bis(methacryloyloxymethyl)ethyl isocyanate.

Examples of the hydroxy group-containing compound represented by Formula (4), which is used as a raw material for the monomer (m-pb), include a malic acid ester, a 2-methylmalic acid ester, a 3-methylmalic acid ester, and a 2,3-dimethylmalic acid ester. Among these, a malic acid ester is preferred from the viewpoints of ease of the conversion reaction to the structural unit (b) having a group represented by Formula (1-1) or (1-2) and ease of availability.

The numbers of carbon atoms in the two ester moieties contained in the hydroxy group-containing compound represented by Formula (4) (the numbers of carbon atoms of R¹ and R⁴ in —COOR¹ and COOR⁴) are each 1 to 20, preferably 1 to 5, and more preferably 1 to 3.

The hydroxy group-containing compound represented by Formula (4) is particularly preferably diethyl malate from the viewpoint of ease of availability.

Specifically, the monomer (m-pb) is preferably one or two or more selected from 2-[(diethyl malate)carbonylamino]ethyl acrylate, [(diethyl malate)carbonylamino]methyl acrylate, 2-[(diethyl malate)carbonylamino]propyl acrylate, and 2-[(diethyl malate)carbonylamino]butyl acrylate, and is particularly preferably 2-[(diethyl malate)carbonylamino]ethyl acrylate from the viewpoint of ease of production.

The content of the structural unit (pb) is preferably 3 to 40 mol %, more preferably 5 to 35 mol %, and still more preferably 10 to 30 mol % in the total structural units of the copolymer (A). When the content of the structural unit (pb) is 3 mol % or more, a sufficient amount of ethylenically unsaturated group can be introduced into the copolymer (A) by the conversion reaction. By using the modified copolymer (A2) into which an ethylenically unsaturated group is introduced in the photosensitive resin composition, favorable low-temperature curability and developability can be obtained. When the content of the structural unit (pb) is 40 mol % or less, the content of the structural unit (a) can be sufficiently ensured, and sufficient developability can be obtained by using the modified copolymer (A2) in the photosensitive resin composition.

### (Structural Unit (c) Having Hydroxy Group)

The copolymer (A) may contain a structural unit (c) having a hydroxy group (also simply referred to as “structural unit (c)”), if necessary. The structural unit (c) is not limited as long as it is a structural unit that does not have an acid group, an ethylenically unsaturated group, or a blocked isocyanate group but has a hydroxy group. As the copolymer (A) has the structural unit (c) having a hydroxy group, crosslinking with a structural unit (d) having a blocked isocyanate group described later progresses during heating. Thus, in a case where the modified copolymer (A2) obtained by converting the copolymer (A) is used in the photosensitive resin composition, favorable solvent resistance of the cured product can be obtained in thermal curing under low temperature conditions as well.

The structural unit (c) having a hydroxy group is preferably a structural unit derived from a monomer (m-c) having a hydroxy group and an ethylenically unsaturated group (hereinafter also simply referred to as monomer (m-c)). Specific examples of the monomer (m-c) include (meth)acrylic acid ester derivatives having a hydroxy group, and specific examples thereof include hydroxyalkyl (meth)acrylates such as 2-hydroxyethyl (meth)acrylate, 2-hydroxypropyl (meth)acrylate, 2-hydroxybutyl (meth)acrylate, 2,3-dihydroxypropyl (meth)acrylate, and 4-hydroxybutyl (meth)acrylate; and 2-hydroxy-3-phenoxypropyl(meth)acrylate. Among these, a hydroxyalkyl (meth)acrylate is preferred from the viewpoint of reactivity during synthesis of the copolymer (A), low-temperature curability of the photosensitive resin composition containing the modified copolymer (A2), and ease of availability. As the hydroxyalkyl (meth)acrylate, 2-hydroxyethyl (meth)acrylate, 2-hydroxypropyl (meth)acrylate, and 4-hydroxybutyl (meth)acrylate are preferred, and 4-hydroxybutyl (meth)acrylate is more preferred from the viewpoint of decreasing the glass transition temperature of the copolymer (A).

The monomer (m-c) having a hydroxy group and an ethylenically unsaturated group may be used singly or in combination of two or more kinds thereof.

The content of the structural unit (c) is preferably 3 to 40 mol %, more preferably 5 to 30 mol %, and still more preferably 8 to 25 mol % in the total structural units of the copolymer (A). When the content of the structural unit (c) is 3 mol % or more, the quantity of crosslinking between the hydroxy group of the structural unit (c) and the blocked isocyanate group of the structural unit (d) can be sufficiently ensured. As a result, the low-temperature curability of the photosensitive resin composition that is obtained using the modified copolymer (A2) obtained by converting the copolymer (A) is improved. When the content of the structural unit (c) is 40 mol % or less, the contents of the structural unit (a) and structural unit (pb) can be sufficiently ensured and a sufficient amount of ethylenically unsaturated group can be introduced into the copolymer (A). Hence, sufficient developability of a cured product of the photosensitive resin composition that is obtained using the modified copolymer (A2) after conversion can be obtained. In addition, since the content of the structural unit (d) can be sufficiently ensured, the quantity of crosslinking with the structural unit (c) can be sufficiently ensured.

### (Structural Unit (d) Having Blocked Isocyanate Group)

The copolymer (A) may contain a structural unit (d) having a blocked isocyanate group (also simply referred to as “structural unit (d)”), if necessary. The structural unit (d) is not particularly limited as long as it is a structural unit that has a blocked isocyanate group, does not have an acid group or an ethylenically unsaturated group and does not correspond to the structural unit (pb). As the copolymer (A) has the structural unit (d) having a blocked isocyanate group, crosslinking with the structural unit (c) having a hydroxy group progresses during heating. Crosslinking is formed, for example, by the reaction of an isocyanate group generated by dissociation of the blocking agent with a hydroxy group. In a case where the blocking agent is a compound having a carboxylic acid alkyl ester structure, crosslinking can be formed by transesterification of the carboxylic acid alkyl ester structure with a hydroxy group described later although dissociation of the blocking agent is not caused. Thus, in a case where the modified copolymer (A2) is used in the photosensitive resin composition, favorable solvent resistance of the cured product can be obtained in thermal curing under low temperature conditions as well.

The structural unit (d) having a blocked isocyanate group has a structure in which an isocyanate group is blocked with a blocking agent. The reaction of the isocyanate group with the blocking agent can be performed regardless of the presence or absence of a solvent. In a case of using a solvent, it is required to use a solvent that is inert to the isocyanate group. In the blocking reaction, organic metal salts of tin, zinc, lead, and the like, tertiary amines, and the like may be used as catalysts. The blocking reaction can generally be performed at −20° C. to 150° C., and is preferably performed at 0° C. to 100° C.

Examples of the blocking agent that blocks an isocyanate group include lactam compounds such as s-caprolactam, 6-valoractam, γ-butylolactam, and β-propiolactam; alcohol compounds such as methanol, ethanol, propanol, butanol, ethylene glycol, methyl cellosolve, butyl cellosolve, methyl carbitol, benzyl alcohol, phenyl cellosolve, furfuryl alcohol, and cyclohexanol; phenol compounds such as phenol, cresol, 2,6-xylenol, 3,5-xylenol, ethylphenol, o-isopropylphenol, butylphenol such as p-tert-butylphenol, p-tert-octylphenol, nonylphenol, dinonylphenol, styrenated phenol, methyl 2-hydroxybenzoate, methyl 4-hydroxybenzoate, thymol, 1-naphthol, p-nitrophenol, and p-chlorophenol; active methylene compounds such as dimethyl malonate, diethyl malonate, methyl acetoacetate, ethyl acetoacetate, and acetylacetone; mercaptan compounds such as butyl mercaptan, thiophenol, and tert-dodecyl mercaptan; amine compounds such as diphenylamine, phenylnaphthylamine, aniline, and carbazole; acid amide compounds such as acetanilide, acetanisidide, acetic acid amide, and benzamide; imide compounds such as succinimide and maleimide; imidazole compounds such as imidazole, 2-methylimidazole, and 2-ethylimidazole; pyrazole compounds such as pyrazole and 3,5-dimethylpyrazole; urea compounds such as urea, thiourea, and ethylene urea; carbamic acid compounds such as phenyl N-phenylcarbamate and 2-oxazolidone: imine compounds such as ethyleneimine and polyethylenimine; oxime compounds such as formaldoxime, acetaldoxime, acetoxime, methyl ethyl ketoxime, methyl isobutyl ketoxime, and cyclohexanone oxime; and bisulfites such as sodium bisulfite and potassium bisulfite.

The blocking agents may be used singly or in combination of two or more kinds thereof.

In an embodiment, as the blocking agent, from the viewpoint of improving the low-temperature curability and solvent resistance as a photosensitive resin composition, a blocking agent that has a dissociation rate of blocked isocyanate group of 5% to 99% by mass in a case of being heated at 100° C. for 30 minutes is preferred, one or more selected from the group consisting of 3,5-dimethylpyrazole, methyl ethyl ketoxime, methyl 4-hydroxybenzoate, methyl 2-hydroxybenzoate, and 3,5-xylenol are more preferred, and 3,5-dimethylpyrazole is still more preferred.

In the present specification, the dissociation rate of blocked isocyanate group is defined as the value determined by measuring the mass decrease proportion of the blocked isocyanate group-containing compound by HPLC analysis after a n-octanol solution containing a blocked isocyanate group-containing compound at a concentration of 20% by mass is prepared, 1 mass %-equivalent dibutyltin laurate and 3 mass %-equivalent phenothiazine (polymerization inhibitor) are added to the solution, and then heating is performed at 100° C. for 30 minutes. As the blocked isocyanate group-containing compound, a compound in which the isocyanate group of 2-isocyanatoethyl acrylate is blocked with the blocking agent to be measured is used. When a blocking agent having a dissociation rate in the above range is used, the stability of the copolymer (A) during synthesis can be sufficiently ensured, the baking temperature during the formation of cured film can be set sufficiently low, and the solvent resistance of cured film can be sufficiently ensured.

In an embodiment, a blocking agent having a carboxylic acid alkyl ester structure is also preferred as the blocking agent from the viewpoint of improving the low-temperature curability and solvent resistance as a photosensitive resin composition. In this case, the structural unit (d) having a blocked isocyanate group has a carboxylic acid alkyl ester structure. The carboxylic acid alkyl ester structure means a structure having an alkyloxycarbonyl group, and a structure having an alkyloxycarbonyl group in which the alkyl group has 1 to 10 carbon atoms is preferred. As the photosensitive resin composition containing the modified copolymer (A2) is heated, the alkyloxycarbonyl group undergoes transesterification with the hydroxy group of the structural unit (c) to form a crosslinked structure. Therefore, the photosensitive resin composition that is obtained using the modified copolymer (A2) obtained by converting the copolymer (A) containing a structural unit having a carboxylic acid alkyl ester structure can afford a cured film exhibiting excellent solvent resistance when cured at a low temperature of 50° C. to 150° C. as well.

The structural unit having a carboxylic acid alkyl ester structure is more preferably a structural unit having a group represented by the following Formula (2) or a group represented by the following Formula (3).

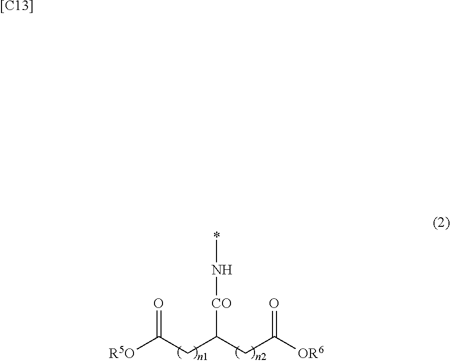

(in Formula (2), R⁵ and R⁶ each independently represent an alkyl group having 1 to 10 carbon atoms, n1 and n2 each independently represent an integer of 0 to 2, and * represents a linking site with a residue obtained by removing the blocked isocyanate group from the structural unit (d))

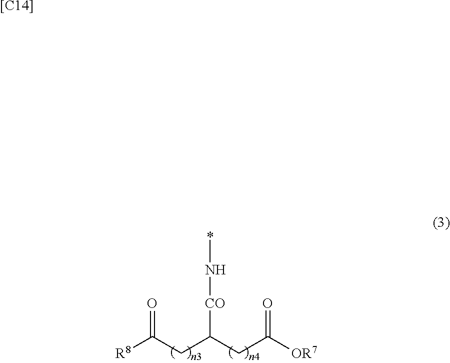

(in Formula (3), R⁷ and R⁸ each independently represent an alkyl group having 1 to 10 carbon atoms, n3 and n4 each independently represent an integer of 0 to 2, and * represents a linking site with a residue obtained by removing the blocked isocyanate group from the structural unit (d))

The group represented by Formula (2) does not have to be of one kind. R⁵ of each structural unit may be different, R⁶ of each structural unit may also be different, n1 of each structural unit may also be different, and n2 of each structural unit may also be different. The same applies to the group represented by Formula (3).

In Formula (2), R⁵ and R⁶ are each independently an alkyl group having 1 to 10 carbon atoms. R⁵ and R⁶ are each independently preferably an alkyl group having 2 to 6 carbon atoms, more preferably an alkyl group having 2 to 3 carbon atoms, and most preferably R⁵ and R⁶ are both ethyl groups.

In a case where R⁵ and R⁶ are ethyl groups, R⁵ and R⁶ undergo transesterification with the hydroxy group of the structural unit (c) to generate ethanol when the photosensitive resin composition containing the modified copolymer (A2) is thermally cured. Ethanol generated during the thermal curing of the photosensitive resin composition is preferred since ethanol is easily evaporated and removed by heating to thermally cure the photosensitive resin composition.

In Formula (2), n1 and n2 each independently represent an integer of 0 to 2. Preferably, n1 and n2 are each independently 0 or 1, and more preferably both of n1 and n2 are 0.

In Formula (3), R⁷ and R⁸ are each independently an alkyl group having 1 to 10 carbon atoms. R⁷ is preferably an alkyl group having 2 to 6 carbon atoms, more preferably an alkyl group having 2 to 3 carbon atoms, and still more preferably an ethyl group.

In a case where R⁷ is an ethyl group, R⁷ undergoes transesterification with the hydroxy group of the structural unit (c) to generate ethanol when the photosensitive resin composition containing the modified copolymer (A2) is thermally cured. Ethanol generated during the thermal curing of the photosensitive resin composition is preferred since ethanol is easily evaporated and removed by heating to thermally cure the photosensitive resin composition.

R⁸ is preferably an alkyl group having 1 to 6 carbon atoms, more preferably an alkyl group having 1 to 3 carbon atoms, and still more preferably a methyl group.

In Formula (3), n3 and n4 each independently represent an integer of 0 to 2. Preferably, n3 and n4 are each independently 0 or 1, and more preferably both of n3 and n4 are 0.

From the viewpoint of ease of transesterification with the hydroxy group of the structural unit (c) and low-temperature curability as a photosensitive resin composition, the structural unit (d) preferably has a group represented by Formula (2).

The structural unit (d) having a blocked isocyanate group is preferably a structural unit derived from a monomer (m-d) having a blocked isocyanate group and an ethylenically unsaturated bond (also simply referred to as monomer (m-d)). The monomer (m-d) may be used singly or in combination of two or more kinds thereof. Specific examples of the group having an ethylenically unsaturated bond include a vinyl group and a (meth)acryloyloxy group.

Examples of the monomer (m-d) include a reaction product of an isocyanate compound having an ethylenically unsaturated group with a blocking agent. As the isocyanate compound having an ethylenically unsaturated group, those similar to the isocyanate compounds used as a raw material for the monomer (m-pb) described above can be used.

The structural unit having a group represented by Formula (2) or (3) is preferably a structural unit derived from a monomer having a group represented by Formula (2) or (3) and an ethylenically unsaturated bond. Examples of the group having an ethylenically unsaturated bond include a vinyl group and a (meth)acryloyloxy group.

Examples of the monomer having a group represented by Formula (2) or (3) and an ethylenically unsaturated bond include a reaction product of an isocyanate compound having an ethylenically unsaturated group with a malonic acid diester or an acetoacetic acid ester.

As the isocyanate compound having an ethylenically unsaturated group, those similar to the isocyanate compounds used as a raw material for the monomer (m-pb) described above can be used.

Examples of the malonic acid diester include dimethyl malonate, diethyl malonate, di(n-propyl) malonate, and di(i-propyl) malonate, and diethyl malonate and dimethyl malonate are preferred from the viewpoints of ease of availability, cost, and quality.

Examples of the acetoacetic acid ester include methyl acetoacetate and ethyl acetoacetate.

Specific examples of the monomer having a group represented by Formula (2) and an ethylenically unsaturated bond include Karenz (trademark) MOI-DEM (Resonac Corporation) and Karenz (trademark) AOI-DEM (Resonac Corporation).

The reaction of an isocyanate compound having an ethylenically unsaturated group with a malonic acid diester or acetoacetic acid ester can be performed regardless of the presence or absence of a solvent. In a case where the reaction is performed using a solvent, the solvent inert to the isocyanate group is used. In the reaction, organic metal salts of tin, zinc, lead, and the like, tertiary amines, and the like may be used as catalysts.

The reaction can generally be performed at a temperature of −20° C. to 150° C., preferably at a temperature of 25° C. to 130° C. When the reaction temperature is −20° C. or more, a sufficient reaction rate can be obtained. Meanwhile, when the reaction temperature is 150° C. or less, gelation due to the polymerization of a raw material having a C═C (double bond) can be prevented.

The content of the structural unit (d) is preferably 5 to 45 mol %, more preferably 10 to 40 mol %, and still more preferably 15 to 35 mol % in the total structural units of the copolymer (A). When the content of the structural unit (d) is 5 mol % or more, the quantity of crosslinking between the blocked isocyanate group of the structural unit (d) and the hydroxy group of the structural unit (c) can be sufficiently ensured. As a result, the low-temperature curability of the photosensitive resin composition that is obtained using the modified copolymer (A2) obtained by converting the copolymer (A) is improved. When the content of the structural unit (d) is 45 mol % or less, the contents of the structural unit (a) and structural unit (pb) can be sufficiently ensured, the contents of the structural unit (a) and structural unit (b) of the modified copolymer (A2) can be sufficiently ensured, and thus sufficient developability of a cured product can be obtained. In addition, the content of the structural unit (c) can be sufficiently ensured, and the quantity of crosslinking with the structural unit (d) can be sufficiently ensured.

(Structural Unit (e) Other Than Structural Units (a) to (d) and Structural Unit (pb))

The copolymer (A) may contain a structural unit (e) other than the structural units (a) to (d) and structural unit (pb) (also simply referred to as “structural unit (e)”), if necessary. The structural unit (e) is a structural unit other than the structural units (a) to (d) and structural unit (pb), which does not have an acid group, an ethylenically unsaturated group, a hydroxy group, or a blocked isocyanate group. As the copolymer (A) has the structural unit (e), it is possible to impart additionally required functions.

The structural unit (e) is a structural unit derived from another monomer (m-e) having an ethylenically unsaturated group, which is copolymerizable with the monomers (m-a), (m-pb), (m-c), and (m-d), (also simply referred to as monomer (m-e)). Specific examples thereof include aromatic vinyl compounds, cyclic olefins having a norbornene structure, dienes, (meth)acrylic acid esters, (meth)acrylamides, vinyl compounds, unsaturated dicarboxylic acid diesters, monomaleimides, glycidyl (meth)acrylate, (meth)acrylic acid anilide, (meth)acrylonitrile, and acrolein.

Examples of the aromatic vinyl compounds include styrene, α-methylstyrene, o-vinyltoluene, p-vinyltoluene, o-chlorostyrene, m-chlorostyrene, methoxystyrene, p-nitrostyrene, p-cyanostyrene, and p-acetylaminostyrene.

Examples of the cyclic olefins having a norbornene structure include norbornene(bicyclo[2.2.1]hept-2-ene), 5-methylbicyclo[2.2.1]hept-2-ene, tetracyclo[4.4.0.1^{2,5}.1^{7,10}]dodeca-3-ene, 8-ethyltetracyclo[4.4.0.1^{2,5}.1^{7,10}]dodeca-3-ene, dicyclopentadiene, tricyclo[5.2.1.0^{2,6}]deca-8-ene, tricyclo[4.4.0.1^{2,5}]undeca-3-ene, tricyclo[6.2.1.0^{1,8}]undeca-9-ene, tetracyclo[4.4.0.1^{2,5}.1^{7,10}.0^{1,6}]dodeca-3-ene, 8-ethylidenetetracyclo[4.4.0.1^{2,5}.1^{7,12}]dodeca-3-ene, and pentacyclo[6.5.1.1^{3,6}.0^{2,7}.0^{9,13}]pentadeca-4-ene.

Examples of the dienes include butadiene, isoprene, and chloroprene.

Examples of the (meth)acrylic acid esters include methyl (meth)acrylate, ethyl (meth)acrylate, isopropyl (meth)acrylate, tert-butyl (meth)acrylate, pentyl (meth)acrylate, benzyl (meth)acrylate, isoamyl (meth)acrylate, 2-ethylhexyl (meth)acrylate, lauryl (meth)acrylate, dodecyl (meth)acrylate, cyclohexyl (meth)acrylate, methylcyclohexyl (meth)acrylate, rosin (meth)acrylate, norbornyl (meth)acrylate, 5-ethylnorbornyl (meth)acrylate, dicyclopentenyl (meth)acrylate, dicyclopentanyl (meth)acrylate, dicyclopentenyl oxyethyl acrylate, isobornyl (meth)acrylate, adamantyl (meth)acrylate, tetrahydrofurfuryl (meth)acrylate, 1,1,1-trifluoroethyl (meth)acrylate, perfluoroethyl (meth)acrylate, perfluoro-n-propyl (meth)acrylate, 3-(N,N-dimethylamino)propyl (meth)acrylate, triphenylmethyl (meth)acrylate, phenyl (meth)acrylate, cumyl (meth)acrylate, 4-phenoxyphenyl (meth)acrylate, phenoxyethyl (meth)acrylate, phenoxy polyethylene glycol (meth)acrylate, nonylphenoxy polyethylene glycol mono(meth)acrylate, biphenyloxyethyl (meth)acrylate, naphthalene (meth)acrylate, anthracene (meth)acrylate, and ethoxylated phenyl (meth)acrylate.

Examples of the (meth)acrylamides include (meth)acrylamide, N,N-dimethyl(meth)acrylamide, N,N-diisopropyl(meth)acrylamide, and anthracenyl(meth)acrylamide.

Examples of the vinyl compounds include vinyl chloride, vinylidene chloride, vinyl fluoride, vinylidene fluoride, N-vinylpyrrolidone, vinylpyridine, vinyl acetate, and vinyltoluene.

Examples of the unsaturated dicarboxylic acid diesters include diethyl citraconate, diethyl maleate, diethyl fumarate, and diethyl itaconate.

Examples of the monomaleimides include N-phenylmaleimide, N-cyclohexylmaleimide, and N-laurylmaleimide.

Among these, from the viewpoint of ease of availability and reactivity during synthesis of the copolymer (A), aromatic vinyl compounds, aromatic group-containing (meth)acrylates, and alkyl (meth)acrylates having an alkyl group having 1 to 12 carbon atoms are preferred, styrene, benzyl (meth)acrylate, dicyclopentanyl (meth)acrylate, 2-ethylhexyl (meth)acrylate, and methyl (meth)acrylate are more preferred, and 2-ethylhexyl (meth)acrylate and methyl (meth)acrylate are still more preferred.

The monomer (m-e) may be used singly or in combination of two or more kinds thereof.

In a case where the copolymer (A) contains the structural unit (e), the content of the structural unit (e) is preferably 1 to 50 mol %, more preferably 3 to 45 mol %, and still more preferably 5 to 40 mol % in the total structural units of the copolymer (A). By setting the content of the structural unit (e) within the above ranges, while the functions of the structural units (a), (pb), (c), and (d) are sufficiently ensured, additional functions by the structural unit (e) can be imparted or the functions obtained from the structural units (a), (pb), (c), and (d) can be adjusted to proper ranges.

### [Basic Catalyst (B)]

The basic catalyst (B) is a basic catalyst having a pKa (acidity constant; also called acid dissociation constant) of 4 to 12 at 25° C. The pKa of the basic catalyst (B) at 25° C. is 12 or less, or may be 11 or less, or may be 10 or less. The pKa of the basic catalyst (B) at 25° C. is 4 or more, or may be 5 or more, may be 6 or more, or may be 7 or more. The combination of these lower and upper limit values may be any composition. When the pKa at 25° C. is 4 or more, a high conversion rate from the structural unit (pb) to the structural unit (b) can be obtained. When the pKa of the basic catalyst (B) at 25° C. is 12 or less, the conversion speed from the structural unit (pb) to the structural unit (b) is controlled in a proper range, and the structural unit (b) can be prevented from being consumed through a further reaction. In addition, the storage stability as a photosensitive resin composition is favorable, and therefore favorable developability can be obtained. The basic catalyst (B) having a pKa of 4 or more at 25° C. includes those having a pKa of 4 or more in an aqueous solution and those which are too acidic to be measured in an aqueous solution but of which the pKa in an aqueous solution converted from the results measured in an organic solvent is 4 or more.

Specific examples of the basic catalyst (B) include pyridine and pyridine derivatives, imidazole compounds, alkylamines, and cyclic diamines. A “C1-4 alkyl” means that the alkyl group has 1 to 4 carbon atoms.

Specific examples of the pyridine and pyridine derivatives include pyridine (pKa 5.2); C1-4 alkylpyridines such as methylpyridine (picoline) (pKa 6.75) and ethylpyridine; di-C1-4 alkylpyridines such as dimethylpyridine (lutidine) (pKa 6.47 to 6.6); tri-C1-4 alkylpyridines such as trimethylpyridine (collidine) (pKa 7.48); 4-aminopyridine derivatives having an amino group at the 4-position, such as 4-aminopyridine (pKa 9.17), 4-dimethylaminopyridine (pKa 9.7), 4-diethylaminopyridine, 4-pyrrolidinopyridine, 4-piperidinopyridine, and 2-methyl-4-dimethylaminopyridine. Among these, from the viewpoint of the conversion efficiency of the structural unit (pb) contained in the copolymer (A), a 4-aminopyridine derivative is preferred, a 4-aminopyridine derivative having a tertiary amino group at the 4-position is more preferred, a 4-di-C1-4 alkylaminopyridine is still more preferred, and 4-dimethylaminopyridine is particularly preferred.

Examples of the imidazole compounds include 2-methylimidazole (pKa 7.75) and 1,2-dimethylimidazole (pKa 7.8).

Examples of the alkylamines include diisopropylamine (pKa 11.05), trimethylamine, and triethylamine (pKa 10.7).

Examples of the cyclic diamines include 1,4-diazabicyclo[2.2.2]octane (DABCO) (pKa 8.8).

Among these, because of their high nucleophilic properties due to resonance stabilization, it is preferable to use at least one selected from the group consisting of pyridine, pyridine derivatives, and imidazole compounds, it is more preferable to use at least one selected from the group consisting of pyridine derivatives and imidazole compounds, and it is still more preferable to use a 4-aminopyridine derivative. Thus, the structural unit (pb) contained in the copolymer (A) can be efficiently converted to introduce an ethylenically unsaturated group. Therefore, the copolymer (A) can be efficiently converted to the modified copolymer (A2) described later. The photosensitive resin composition obtained using the modified copolymer (A2) is excellent in low-temperature curability and developability, and can afford a cured film excellent in solvent resistance.

In an embodiment, the basic catalyst (B) is preferably at least one selected from pyridine, 4-dimethylaminopyridine, 1,2-dimethylimidazole, triethylamine, and 1,4-diazabicyclo[2.2.2]octane, more preferably at least one selected from 4-dimethylaminopyridine, 1,2-dimethylimidazole, triethylamine, and 1,4-diazabicyclo[2.2.2]octane, and still more preferably at least one selected from 4-dimethylaminopyridine, triethylamine, and 1,4-diazabicyclo[2.2.2]octane.

The basic catalyst (B) may be used singly or in combination of two or more kinds thereof.

The content of the basic catalyst (B) is preferably 0.01 to 10 parts by mass, more preferably 0.1 to 8 parts by mass, and still more preferably 0.5 to 6 parts by mass, with respect to 100 parts by mass of the copolymer (A). It is preferable that the content of the basic catalyst (B) be 0.01 parts by mass or more since the reaction speed for converting the structural unit (pb) contained in the copolymer (A) to the structural unit (b) is likely to be sufficiently fast. When the content of the basic catalyst (B) is 10 parts by mass or less, the influence of the basic catalyst (B) can be suppressed when a photosensitive resin composition containing the modified copolymer (A2) obtained by converting the copolymer (A) is cured.

### [Solvent (C)]

Examples of the solvent (C) include hydroxy group-containing solvents such as (poly)alkylene glycol monoalkyl ethers such as ethylene glycol monomethyl ether, ethylene glycol monoethyl ether, diethylene glycol monomethyl ether, diethylene glycol mono-n-butyl ether, triethylene glycol monomethyl ether, propylene glycol monomethyl ether, propylene glycol monoethyl ether, dipropylene glycol monomethyl ether, tripropylene glycol monoethyl ether, and 3-methoxy-1-butanol; hydroxy group-containing carboxylic acid esters such as methyl 2-hydroxypropionate, ethyl 2-hydroxypropionate, methyl 2-hydroxy-2-methylpropionate, ethyl 2-hydroxy-2-methylpropionate, ethyl hydroxyacetate, and methyl 2-hydroxy-3-methylbutyrate; and diethylene glycol; as well as hydroxy group-free solvents such as (poly)alkylene glycol monoalkyl ether acetates such as ethylene glycol monomethyl ether acetate, ethylene glycol monoethyl ether acetate, propylene glycol monomethyl ether acetate, and propylene glycol monoethyl ether acetate; other ethers such as diethylene glycol dimethyl ether, diethylene glycol methyl ethyl ether, diethylene glycol diethyl ether, and tetrahydrofuran; ketones such as methyl ethyl ketone, cyclohexanone, 2-heptanone, and 3-heptanone; esters such as methyl 3-methoxypropionate, methyl 3-ethoxypropionate, ethyl ethoxyacetate, 3-methyl-3-methoxybutyl acetate, 3-methyl-3-methoxybutyl propionate, ethyl acetate, n-butyl acetate, i-propyl acetate, i-butyl acetate, n-amyl acetate, i-amyl acetate, n-butyl propionate, ethyl butyrate, n-propyl butyrate, i-propyl butyrate, ethyl pyruvate, n-propyl pyruvate, methyl acetoacetate, ethyl acetoacetate, and ethyl 2-oxobutyrate; aromatic hydrocarbons such as toluene and xylene; and carboxylic acid amides such as N-methylpyrrolidone, N,N-dimethylformamide, and N,N-dimethylacetamide. The solvents (C) can be used singly or in combination of two or more kinds thereof.

Among these solvents (C), from the viewpoints of ease of availability, cost, and stability during resist preparation, it is preferable to use ethers such as (poly)alkylene glycol monoalkyl ethers, (poly)alkylene glycol monoalkyl ether acetates, and other ethers, and specifically, it is more preferable to use one or two or more selected from propylene glycol monomethyl ether acetate, diethylene glycol methyl ethyl ether, propylene glycol monomethyl ether, ethylene glycol monomethyl ether, and 3-methoxy-1-butanol.

The content of the solvent (C) is preferably 30 to 1,000 parts by mass, and more preferably 50 to 800 parts by mass, with respect to 100 parts by mass of the sum of the components other than the solvent (C). It is preferable that the content of the solvent (C) be 30 parts by mass or more since a stable reaction can be performed when the structural unit (pb) contained in the copolymer (A) is converted. It is preferable that the content of the solvent (C) be 1,000 parts by mass or less since the viscosity of the resin composition can be suitably adjusted.

### [Method for Producing Copolymer (A)]

The copolymer (A) can be produced by copolymerizing the monomers (m-a) and (m-pb) corresponding to the structural units (a) and (pb) contained in the copolymer (A), respectively. The proportions of the structural units (a) and (pb) contained in the copolymer (A) are equal to the proportions of the respective monomers (m-a) and (m-pb) in the sum of all the monomers used as raw materials for the copolymer (A) (hereinafter sometimes referred to as “raw material monomers”).

Thus, the proportions of the respective monomers (m-a) and (m-pb) in the raw material monomers used as the raw materials for the copolymer (A) are preferably 5 to 50 mol % (m-a) and 3 to 40 mol % (m-pb), more preferably 8 to 40 mol % (m-a) and 5 to 35 mol % (m-pb), and still more preferably 10 to 30 mol % (m-a) and 10 to 30 mol % (m-pb).

In the case of producing one containing the structural unit (c) as the copolymer (A), as the raw material monomers for the copolymer (A), the monomer (m-c) may be further used in addition to the monomers (m-a) and (m-pb). In that case, the proportion of the monomer (m-c) in the raw material monomers used as the raw materials for the copolymer (A) is preferably 3 to 40 mol %, more preferably 5 to 30 mol %, and still more preferably 8 to 25 mol %.

In the case of producing one containing the structural unit (d) as the copolymer (A), as the raw material monomers for the copolymer (A), the monomer (m-d) may be further used in addition to the monomers (m-a) and (m-pb). In that case, the proportion of the monomer (m-d) in the raw material monomers used as the raw materials for the copolymer (A) is preferably 5 to 45 mol %, more preferably 10 to 40 mol %, and still more preferably 15 to 35 mol %.

In the case of producing one containing the structural unit (e) as the copolymer (A), as the raw material monomers for the copolymer (A), the monomer (m-e) may be further used in addition to the monomers (m-a) and (m-pb). In that case, the proportion of the monomer (m-e) in the raw material monomers used as the raw materials for the copolymer (A) is preferably 1 to 50 mol %, more preferably 3 to 45 mol %, and still more preferably 5 to 40 mol %.

The copolymerization reaction of the raw material monomers (monomers (m-a) and (m-pb) as well as the monomers (m-c), (m-d), and (m-e) used if necessary), which are used when the copolymer (A) is produced, can be performed in the presence or absence of a polymerization solvent according to a radical polymerization method known in the art. Specifically, for example, a method can be used in which a raw material monomer solution is prepared by mixing raw material monomers, a polymerization initiator, and a polymerization solvent, and the polymerization reaction is performed in a nitrogen gas atmosphere at a temperature of 50° C. to 100° C. for 1 to 20 hours.

As the polymerization solvent used when the copolymer (A) is produced, those that can be used as the solvent (C) can be used singly or in combination of two or more kinds thereof.

In a case where the raw material monomers contain the monomers (m-c) and (m-d), the temperature at which the raw material monomers are subjected to the copolymerization reaction is preferably less than the temperature at which the dissociation rate of the blocked isocyanate group of the monomer (m-d) having a blocked isocyanate group and an ethylenically unsaturated bond reaches 80% or more in 30 minutes. This is to suppress gelation caused by the dissociation of the blocked isocyanate group of the monomer (m-d) dissociates to form an isocyanate group in the raw material monomer solution during the copolymerization reaction, and reaction of the formed isocyanate group with the hydroxy group of the hydroxy group-containing monomer (m-c). It is more preferable that the temperature at which the raw material monomers be subjected to the copolymerization reaction be lower than the temperature at which the dissociation rate of the blocked isocyanate group of the monomer (m-d) reaches 80% or more in 30 minutes by 20° C. to 50° C.

Specifically, the temperature at which the raw material monomers are subjected to the copolymerization reaction can be 50° C. to 100° C., preferably 60° C. to 90° C., and more preferably 65° C. to 85° C.

Examples of the polymerization initiator used when the raw material monomers are subjected to the copolymerization reaction include 2,2′-azobis(2,4-dimethylvaleronitrile), azobisisobutyronitrile, azobisisovaleronitrile, benzoyl peroxide, and t-butylperoxy-2-ethylhexanoate. The polymerization initiators may be used singly or in combination of two or more kinds thereof. The amount of the polymerization initiator used can be set to 0.5 to 20 parts by mass and is preferably 1.0 to 16 parts by mass, with respect to 100 parts by mass of the raw material monomers (total amount of monomers charged).

When the copolymer (A) is produced, additives such as a polymerization inhibitor, a chain transfer agent, a photosensitizer, a filler, and a plasticizer may be used if necessary as long as the effects of the present invention are not impaired.

### [Method for Producing Resin Composition]

The resin composition can be obtained by mixing the copolymer (A), the basic catalyst (B), and the solvent (C). In a case where the copolymer (A) is synthesized by the above-described production method, the resin composition can also be produced by adding the basic catalyst (B) to the reaction solution. In this case, the solvent used in the synthesis of the copolymer (A) may be used as it is as the solvent (C), or a new solvent may be added.

### <Modified Resin Composition>

A modified resin composition of an embodiment contains a modified copolymer (A2), a basic catalyst (B), and a solvent (C). The modified resin composition may contain a copolymer (A).

As the basic catalyst (B) and the solvent (C), those the same as the basic catalyst (B) and the solvent (C) used in the resin composition may be used, and the same applies to the preferred embodiments and blended amounts. The amount of the basic catalyst (B) blended is determined on the basis of 100 parts by mass of the sum of the copolymer (A) and modified copolymer (A2).

### [Modified Copolymer (A2)]

The modified copolymer (A2) of an embodiment contains a structural unit (a) having an acid group, a structural unit (pb) having a group represented by the following Formula (1), and a structural unit (b) having a group represented by the following Formula (1-1) or (1-2). The modified copolymer (A2) can be obtained by converting a part of the structural units (pb) of the copolymer (A) to the structural unit (b) by the dealcoholization reaction and decarboxylation reaction of the structural unit (pb) by the action of the basic catalyst (B). As the modified copolymer (A2) has the structural unit (b) having an ethylenically unsaturated group, favorable photo-curability can be obtained in a case where the modified copolymer (A2) is used in the photosensitive resin composition, and low-temperature curability is improved. In addition, in a case where the modified copolymer (A2) is used together with a reactive diluent (D) described later, the ethylenically unsaturated group of the structural unit (b) reacts with the reactive diluent (D) to afford favorable adhesive properties of the cured film to the base material.

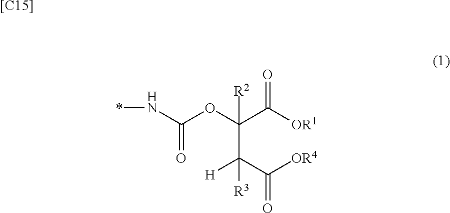

(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb))

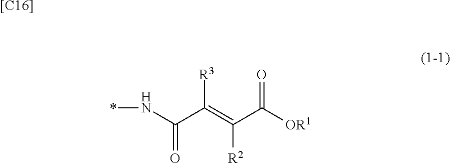

(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b))

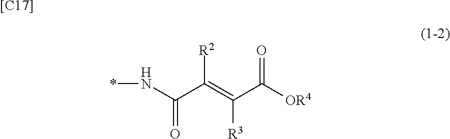

(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b))

The modified copolymer (A2) may further contain the structural unit (c) having a hydroxy group and the structural unit (d) having a blocked isocyanate group, if necessary. The modified copolymer (A2) may further contain the structural unit (e) other than the structural units (a) to (d) and structural unit (pb), if necessary.

As the structural units (a), (pb), (c), (d), and (e), those the same as the structural units (a), (pb), (c), (d), and (e) of the copolymer (A) can be used. The same applies to the preferred embodiments, except for the content of the structural unit (pb).

The content of the structural unit (pb) is preferably 1 to 35 mol %, more preferably 2 to 30 mol %, and still more preferably 3 to 25 mol % in the total structural units of the modified copolymer (A2) and copolymer (A).

### (Structural Unit (b) Having Group Represented by Formula (1-1) or (1-2))

The structural unit (b) having a group represented by Formula (1-1) or (1-2) (also simply referred to as “structural unit (b)”) is a structural unit that does not have an acid group but has a group represented by the following Formula (1-1) or (1-2).

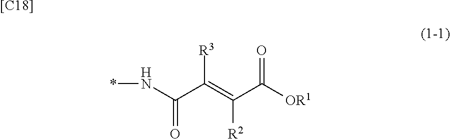

(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b))

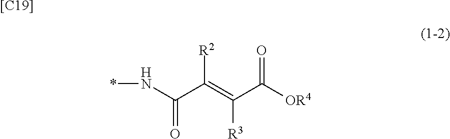

(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b))

The group represented by Formula (1-1) does not have to be of one kind. R¹ of each structural unit may be different, R² of each structural unit may also be different, and R³ of each structural unit may also be different. The same applies to the group represented by Formula (1-2).

In Formulas (1-1) and (1-2), R¹, R², R³ and R⁴ are the same as those described above for Formula (1).

The content of the structural unit (b) is preferably 2 to 39 mol %, more preferably 3 to 33 mol %, and still more preferably 7 to 27 mol % in the total structural units of the modified copolymer (A2) and copolymer (A).

(Reaction Path) In the conversion reaction from the copolymer (A) to the modified copolymer (A2), it is estimated that the structural unit (pb) contained in the copolymer (A) is converted to the structural unit (b) through the reaction path presented below.

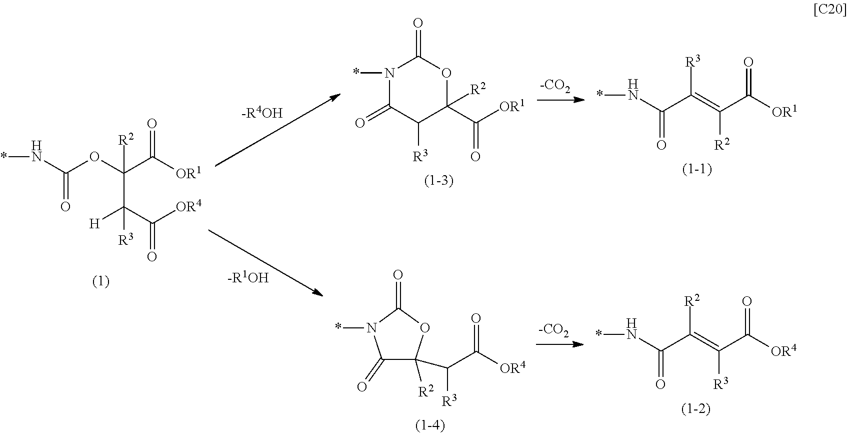

In other words, in the structural unit (pb) having a group represented by Formula (1), which is contained in the copolymer (A), the dealcoholization reaction by H of —NH— in the urethane bond and an ester moiety (—COOR¹ or —COOR⁴) occurs.

Thus, a group having a heterocyclic ring represented by Formula (1-3) and/or Formula (1-4) is formed. The group having a heterocyclic ring represented by Formula (1-3) is formed by the dealcoholization reaction (—R⁴OH) of the ester moiety containing R⁴ in the group represented by Formula (1). The group having a heterocyclic ring represented by Formula (1-4) is formed by the dealcoholization reaction (—R¹OH) of the ester moiety containing R¹ in the group represented by Formula (1).

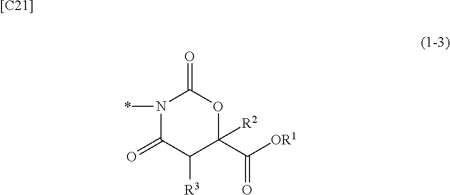

(in formula (1-3), R¹, R² and R³ are the same as R¹, R² and R³ in Formula (1), and * represents a linking site with a residue obtained by removing the group represented by Formula (1-3) from the structural unit (pb))

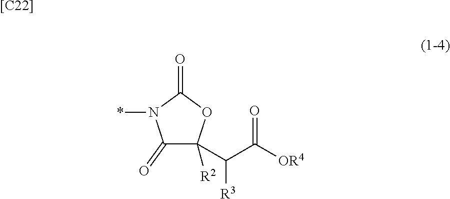

(In formula (1-4), R², R³ and R⁴ are the same as R², R³ and R⁴ in Formula (1), and * represents the linking site with a residue obtained by removing the group represented by Formula (1-4) from the structural unit (pb))

Next, in the group having a heterocyclic ring represented by Formula (1-3), decarboxylation (—CO₂) occurs in the heterocyclic moiety. Thus, the group having a heterocyclic ring represented by Formula (1-3) is converted to the group represented by the following Formula (1-1).

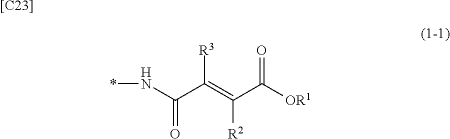

(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b))

Meanwhile, in the group having a heterocyclic ring represented by Formula (1-4), decarboxylation (—CO₂) occurs in the heterocyclic moiety. Thus, the group having a heterocyclic ring represented by Formula (1-4) is converted to the group represented by the following Formula (1-2).

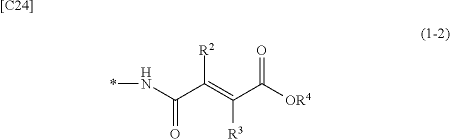

(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b))

As a result of performing the transition state calculation in the product path of each product using the wB97XD as a functional function and the 6-31+g (d) as a basis function in the density functional method, it is presumed that in the conversion reaction for converting the above-described structural unit (pb) to the structural unit (b), the reaction paths of Formula (1), Formula (1-4), and Formula (1-2) have lower activation barriers than the reaction paths of Formula (1), Formula (1-3), and Formula (1-1) and are the main conversion routes. Therefore, it is presumed that in the modified copolymer (A2), a structural unit having the group represented by Formula (1-2) and a structural unit having the group represented by Formula (1-1) are mixed and the structural unit having the group represented by Formula (1-2) is present in a larger amount than the structural unit having the group represented by Formula (1-1).

### [Ethylenically Unsaturated Group Equivalent of Modified Copolymer (A2)]

The ethylenically unsaturated group equivalent of the modified copolymer (A2) is preferably 300 g/mol or more, more preferably 500 g/mol or more, and still more preferably 1,000 g/mol or more. The ethylenically unsaturated group equivalent of the modified copolymer (A2) is preferably 10,000 g/mol or less, more preferably 7,000 g/mol or less, and still more preferably 4,000 g/mol or less. The combination of these lower and upper limit values may be any combination. When the ethylenically unsaturated group equivalent is 300 g/mol or more, the storage stability as a photosensitive resin composition is favorable. When the ethylenically unsaturated group equivalent is 10,000 g/mol or less, the solvent resistance of a cured product is favorable in a case of performing curing at a low temperature.

The “ethylenically unsaturated group equivalent” is the mass of a polymer per mole of ethylenically unsaturated groups of the polymer. The ethylenically unsaturated group equivalent (g/mol) of the modified copolymer (A2) is determined by dividing the mass of the modified copolymer (A2) by the number of moles of the ethylenically unsaturated group contained in the modified copolymer (A2).

In this specification, in a case where R² and R³ in Formulas (1-1) and (1-2) in the modified copolymer (A2) are all hydrogen atoms, the ethylenically unsaturated group equivalent is a value that is calculated from the conversion rate from the structural unit (pb) to the structural unit (b) calculated from the area ratio in an NMR spectrum acquired using an NMR apparatus (for example, Bruker ULTRA SHIELD PLUS 400 (400 MHz), Bruker Corporation) under the following conditions and the charged amounts of the monomers (m-a), (m-pb), and (m-c) to (m-e) used when the copolymer (A) is produced. The measurement sample may contain the copolymer (A). In this case, the value acquired for the mixture of the modified copolymer (A2) and copolymer (A) is determined as the ethylenically unsaturated group equivalent of the modified copolymer (A2). In a case where the measurement sample includes the copolymer (A), the conversion rate from the structural unit (pb) to the structural unit (b) is also the value for the mixture of the modified copolymer (A2) and copolymer (A).

### (NMR Conditions)

Measurement method: ¹H-NMR
Lock solvent: CDCl₃
Internal standard: TSP-d₄ (sodium trimethylsilyl propionate)=0 ppm
Temperature: Room temperature
Sample preparation: Powder sample (20 mg)/CDCl₃ (1 mL)+TSP-d₄ (5 mg)

### (Sample Preparation Method)

The modified copolymer (A2) or a mixture of the modified copolymer (A2) and copolymer (A), which has been dried, is weighed precisely by 20 mg and dissolved in a 20 mL sample bottle by adding CDCl₃ (1 mL), the solution is shaken for 5 minutes using an ultrasonic cleaning machine and then sealed in a 5 mmφ NMR sample tube, and NMR measurement is performed immediately after sampling.

The conversion rate from the structural unit (pb) to the structural unit (b) is calculated by the following equation based on the area ratio of the spectrum of “—CH₂—” of —CR²—CHR³—C(═O)— (that is, —CH—CH₂—C(═O)—) detected at 2.5 to 3.0 ppm to the spectrum of —C(═O)—CR³═CR²—C(═O)— and —C(═O)—CR²═CR³—C(═O)— (that is, —C(═O)—CH═CH—C(═O)—) detected at 6.5 to 7.0 ppm.

$$Conversion rate from structural unit ( pb ) to structural unit ( b ) = \{ ( - C ( = O ) - CH = CH - C ( = O ) - ) / [ ( - CH - {CH}_{2} - C ( = O ) - ) + ( - C ( = O ) - CH = CH - C ( = O ) - ) ] \} \times 100$$

In this specification, in a case where the modified copolymer (A2) contains the structural unit (b) having the group represented by Formula (1-1) or (1-2) in which at least one or both of R² and R³ are hydrocarbon groups having 1 to 20 carbon atoms, the ethylenically unsaturated group equivalent is a value calculated from the amount of halogen bonded to the modified copolymer (A2). The amount of halogen bonded to the modified copolymer (A2) is evaluated in conformity with JIS K 0070: 1992 as follows.

Specifically, the modified copolymer (A2), which has been dried, is dissolved in chloroform, an appropriate amount of Wijs' solution is added thereto, and stirring is performed. Thereafter, the solution is left in a dark place at 23° C. for 1 hour in a state of being sealed. To this solution, potassium iodide solution and water are added, stirring is performed, and the obtained solution is titrated with sodium thiosulfate solution. When the solution turns slightly yellow, a few drops of starch solution is added, and titration is performed until the blue color disappears. The ethylenically unsaturated bonds in the modified copolymer (A2) react with halogen molecules at 1:1. Therefore, the ethylenically unsaturated group equivalent of the modified copolymer (A2) is determined by dividing the mass (g) of the modified copolymer (A2) used in the measurement by the amount of substance (mol) of halogen molecules bonded to the modified copolymer (A2) determined by this measurement. The measurement sample may contain the copolymer (A). In this case, the value obtained for the mixture of the modified copolymer (A2) and copolymer (A) is determined as the ethylenically unsaturated group equivalent of the modified copolymer (A2).

### [Acid Value]

The acid value of the copolymer (A) and the acid value of the modified copolymer (A2) or the mixture of the copolymer (A) and modified copolymer (A2) are preferably 10 KOHmg/g or more, more preferably 15 KOHmg/g or more, and still more preferably 20 KOHmg/g or more. The acid value of the copolymer (A) and the acid value of the modified copolymer (A2) or the mixture of the copolymer (A) and modified copolymer (A2) are preferably 300 KOHmg/g or less, more preferably 200 KOHmg/g or less, and still more preferably 150 KOHmg/g or less. The combination of these lower and upper limit values may be any combination. When the acid values are 10 KOHmg/g or more, the developability is favorable. When the acid values are 300 KOHmg/g or less, the storage stability is favorable.

The “acid value” is the acid value of the curable polymer measured in conformity with JIS K6901:2008 5.3. In other words, the acid value means the number of mg of potassium hydroxide required to neutralize the acidic components contained in 1 g of the copolymer.

### [Weight Average Molecular Weight]

The weight average molecular weight of the copolymer (A) and the weight average molecular weight of the modified copolymer (A2) or the mixture of the copolymer (A) and modified copolymer (A2) are preferably 1,000 or more, more preferably 3,000 or more, and still more preferably 5,000 or more. The weight average molecular weight of the copolymer (A) and the weight average molecular weight of the modified copolymer (A2) or the mixture of the copolymer (A) and modified copolymer (A2) are preferably 50,000 or less, more preferably 40,000 or less, and still more preferably 30,000 or less. The combination of these lower and upper limit values may be any combination. When the weight average molecular weights are 1,000 or more, defects such as chipping are unlikely to occur in the cured resin film after development in a case where the modified copolymer (A2) is used as a raw material for the photosensitive resin composition. When the weight average molecular weights are 50,000 or less, the photosensitive resin composition containing the modified copolymer (A2) has a sufficiently short development time and is excellent in practical use.

In this specification, the weight average molecular weight refers to the weight average molecular weight in terms of standard polystyrene measured by gel permeation chromatography (GPC) under the following conditions.
Column: Two Shodex (trademark) LF-804 (Resonac Corporation) columns connected in series are used.
Column temperature: 40° C.
Sample: 0.2% by mass Tetrahydrofuran solution of measurement target
Developing solvent: Tetrahydrofuran
Detector: Differential refractometer (Shodex (trademark) RI-71S) (Resonac Corporation)
Flow velocity: 1 mL/min

### [Blocked Isocyanate Group Equivalent]

The blocked isocyanate group equivalent of the copolymer (A) and the blocked isocyanate group equivalent of the modified copolymer (A2) or the mixture of the copolymer (A) and modified copolymer (A2) are preferably 100 to 2,000 g/mol, more preferably 200 to 1500 g/mol, and still more preferably 300 to 1300 g/mol. When the blocked isocyanate group equivalent are 100 g/mol or more, the photosensitive resin composition containing the modified copolymer (A2) exhibits more favorable developability. When the blocked isocyanate group equivalent are 2,000 g/mol or less, a cured resin film having a superior hardness can be formed from the photosensitive resin composition containing the modified copolymer (A2).

The “blocked isocyanate group equivalent” is the mass of a polymer per mole of blocked isocyanate groups in the polymer. The blocked isocyanate group equivalent (g/mol) of the copolymer is determined by dividing the mass of the copolymer by the number of moles of the blocked isocyanate groups contained in the copolymer. In this specification, the “blocked isocyanate group equivalent” is a theoretical value calculated from the amounts of monomers charged when the copolymer is produced.

### [Hydroxy Group Equivalent]

The hydroxy group equivalent of the copolymer (A) and the hydroxy group equivalent of the modified copolymer (A2) or the mixture of the copolymer (A) and modified copolymer (A2) are preferably 200 to 5,000 g/mol, more preferably 400 to 4,000 g/mol, and still more preferably 800 to 3,000 g/mol. When the hydroxy group equivalent is 200 g/mol or more, the photosensitive resin composition containing the modified copolymer (A2) exhibits more favorable developability. When the hydroxy group equivalent wight is 5,000 g/mol or less, a cured resin film having a superior hardness can be formed from the photosensitive resin composition containing the modified copolymer (A2).

The “hydroxy group equivalent” is the mass of a polymer per mole of hydroxy groups in the polymer. The hydroxy group equivalent (g/mol) of the copolymer is determined by dividing the mass of the copolymer by the number of moles of the hydroxy groups contained in the copolymer. In this specification, the “hydroxy group equivalent” is a theoretical value calculated from the amounts of monomers charged when the copolymer is produced.

### [Method for Producing Modified Resin Composition]

The modified resin composition can be obtained by converting the structural unit (pb) of the copolymer (A) in the resin composition to the structural unit (b), thereby modifying the copolymer (A) to the modified copolymer (A2). For example, a resin composition containing the copolymer (A), the basic catalyst (B), and the solvent (C) is maintained at a temperature of, for example, 0° C. to 150° C. for 0.1 to 10 hours. The dealcoholization reaction and decarboxylation reaction of the copolymer (A) are thus performed and the structural unit (pb) contained in the copolymer (A) is converted to the structural unit (b), whereby a modified resin composition containing the modified copolymer (A2), the basic catalyst (B), and the solvent (C) can be produced. The copolymer (A) may remain in the modified resin composition in some cases. The content of the copolymer (A) in the modified resin composition may be 0 to 20 parts by mass, 0 to 10 parts by mass, or 0 to 5 parts by mass, with respect to 100 parts by mass of the modified copolymer (A2). In an embodiment, the modified resin composition does not contain the copolymer (A). The temperature condition may be 40° C. or more, 50° C. or more, 60° C. or more, or 70° C. or more. The temperature condition may be 130° C. or less, 110° C. or less, 100° C. or less, or 90° C. or less. The combination of these lower and upper limit values may be any combination. The conversion reaction time may be 30 minutes or more or 60 minutes or more. The conversion reaction time may be 300 minutes or less or 180 minutes or less. The combination of these lower and upper limit values may be any combination.

### <Photosensitive Resin Composition and Photosensitive Coloring Composition>

A photosensitive resin composition of an embodiment contains a modified copolymer (A2), a basic catalyst (B), a solvent (C), a reactive diluent (D), and a photopolymerization initiator (E). The photosensitive resin composition may contain a copolymer (A). A photosensitive coloring composition of an embodiment further contains a coloring agent (F).

The total content of the modified copolymer (A2) and optionally contained copolymer (A) in the photosensitive resin composition or photosensitive coloring composition is preferably 10 parts by mass or more, more preferably 30 parts by mass or more, and still more preferably 60 parts by mass or more, with respect to 100 parts by mass of the sum of the modified copolymer (A2), the copolymer (A), and the reactive diluent (D). The total content of the modified copolymer (A2) and optionally contained copolymer (A) in the photosensitive resin composition or photosensitive coloring composition is preferably 90 parts by mass or less, more preferably 85 parts by mass or less, and still more preferably 80 parts by mass or less, with respect to 100 parts by mass of the sum of the modified copolymer (A2), the copolymer (A), and the reactive diluent (D). The combination of these lower and upper limit values may be any combination. When the total content of the modified copolymer (A2) and copolymer (A) is 10 parts by mass or more, a photosensitive resin composition or photosensitive coloring composition, which exhibits superior low-temperature curability and can afford a cured product exhibiting favorable solvent resistance, can be obtained. When the total content of the modified copolymer (A2) and copolymer (A) is 90 parts by mass or less, the content of the reactive diluent (D) can be sufficiently ensured, and the strength and adhesive properties to a base material of a cured product are favorable.

The content of the copolymer (A) in the photosensitive resin composition or photosensitive coloring composition may be 0 to 20 parts by mass, 0 to 10 parts by mass, or 0 to 5 parts by mass, with respect to 100 parts by mass of the modified copolymer (A2). From the viewpoint of improving the solvent resistance of the cured resin film, the copolymer (A) may not be contained.

The content of the basic catalyst (B) in the photosensitive resin composition or photosensitive coloring composition may be 0.001 parts by mass or more, 0.01 parts by mass or more, or 0.1 parts by mass or more, with respect to 100 parts by mass of the sum of the modified copolymer (A2), the copolymer (A), and the reactive diluent (D). The content of the basic catalyst (B) in the photosensitive resin composition or photosensitive coloring composition is preferably 5 parts by mass or less, more preferably 4 parts by mass or less, and still more preferably 3 parts by mass or less, with respect to 100 parts by mass of the sum of the modified copolymer (A2), the copolymer (A), and the reactive diluent (D). When the content of the basic catalyst (B) is 5 parts by mass or less, the influence of the basic catalyst (B) during curing of the photosensitive resin composition can be suppressed.

### [Solvent (C)]

As the solvent (C), those the same as the solvent (C) used in the resin composition can be used. The solvent (C) in the photosensitive resin composition or photosensitive coloring composition and the solvent (C) used in the production of the modified copolymer (A2) may be the same as or different from each other.

The content of the solvent (C) in the photosensitive resin composition or photosensitive coloring composition is preferably 30 parts by mass or more, and more preferably 50 parts by mass or more, with respect to 100 parts by mass of the sum of the modified copolymer (A2), the copolymer (A), and the reactive diluent (D). The content of the solvent (C) in the photosensitive resin composition or photosensitive coloring composition is preferably 1,000 parts by mass or less, and more preferably 800 parts by mass or less, with respect to 100 parts by mass of the sum of the modified copolymer (A2), the copolymer (A), and the reactive diluent (D). The combination of these lower and upper limit values may be any combination. When the content of the solvent (C) is 30 parts by mass or more, the viscosity of the photosensitive resin composition or photosensitive coloring composition can be adjusted to a proper range. When the content of the solvent (C) is 1,000 parts by mass or less, the solvent (C) can be easily removed in a case of removing the solvent (C) in the coating film formed by applying the photosensitive resin composition or photosensitive coloring composition onto a base material.

### [Reactive Diluent (D)]

The reactive diluent (D) is a monomer having at least one ethylenically unsaturated bond as a polymerizable functional group in the molecule. The reactive diluent (D) may be a monofunctional monomer or a polyfunctional monomer having a plurality of polymerizable functional groups. By containing the reactive diluent (D), the viscosity of the photosensitive resin composition or photosensitive coloring composition can be adjusted to a proper range depending on the application. In addition, the photosensitive resin composition or photosensitive coloring composition contains the reactive diluent (D), thus exhibits favorable photocurability, and can afford a cured product exhibiting favorable strength and adhesive properties to the base material. The reactive diluent (D) may be used singly or in combination of two or more kinds thereof.

Examples of the monofunctional monomer used as the reactive diluent (D) include (meth)acrylamide compounds such as (meth)acrylamide, methylol (meth)acrylamide, methoxymethyl (meth)acrylamide, ethoxymethyl (meth)acrylamide, propoxymethyl (meth)acrylamide, and butoxymethoxymethyl (meth)acrylamide; (meth)acrylates such as methyl (meth)acrylate, ethyl (meth)acrylate, butyl (meth)acrylate, 2-ethylhexyl (meth)acrylate, 2-hydroxyethyl (meth)acrylate, 2-hydroxypropyl (meth)acrylate, 4-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, glycidyl (meth)acrylate, 2,2,2-trifluoroethyl (meth)acrylate, 2,2,3,3-tetrafluoropropyl (meth)acrylate, and half (meth)acrylates of phthalic acid derivatives; aromatic vinyl compounds such as styrene, α-methylstyrene, α-chloromethylstyrene, and vinyltoluene; and carboxylic acid esters such as vinyl acetate and vinyl propionate. The monofunctional monomers may be used singly or in combination of two or more kinds thereof.

Examples of the polyfunctional monomer used as the reactive diluent (D) include (meth)acrylates such as ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerin di(meth)acrylate, pentaerythritol di(meth)acrylate, pentaerythritol tri(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl(meth)acrylate, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylates (for example, reaction products of tolylene diisocyanate, trimethylhexamethylene diisocyanate, hexamethylene diisocyanate, and the like with 2-hydroxyethyl (meth)acrylate), and tri(meth)acrylate of tris(hydroxyethyl)isocyanurate; aromatic vinyl compounds such as divinylbenzene, diallyl phthalate, and diallyl benzene phosphonate; dicarboxylic acid esters such as divinyl adipate; triallyl cyanurate, methylenebis(meth)acrylamide, and condensates of polyhydric alcohols and N-methylol(meth)acrylamide. The polyfunctional monomers may be used singly or in combination of two or more kinds thereof.

Among these monomers, it is preferable to use a polyfunctional (meth)acrylate as the reactive diluent (D), it is more preferable to use a trifunctional or higher functional (meth)acrylate, and it is still more preferable to use trimethylolpropane tri(meth)acrylate, pentaerythritol tri(meth)acrylate, dipentaerythritol penta(meth)acrylate, or dipentaerythritol hexa(meth)acrylate since a photosensitive resin composition or photosensitive coloring composition exhibiting favorable photocurability can be obtained.

The content of the reactive diluent (D) in the photosensitive resin composition or photosensitive coloring composition is preferably 10 parts by mass or more, more preferably 15 parts by mass or more, and still more preferably 30 parts by mass or more, with respect to 100 parts by mass of the sum of the modified copolymer (A2), the copolymer (A), and the reactive diluent (D). The content of the reactive diluent (D) in the photosensitive resin composition or photosensitive coloring composition is preferably 90 parts by mass or less, more preferably 70 parts by mass or less, and still more preferably 60 parts by mass or less, with respect to 100 parts by mass of the sum of the modified copolymer (A2), the copolymer (A), and the reactive diluent (D). The combination of these lower and upper limit values may be any combination. When the content of the reactive diluent (D) is 10 parts by mass or more, the effect obtained by containing the reactive diluent (D) becomes significant. When the content of the reactive diluent (D) is 90 parts by mass or less, the content of the modified copolymer (A2) can be sufficiently ensured, and therefore a photosensitive resin composition or photosensitive coloring composition exhibiting still more favorable low-temperature curability can be obtained.

### [Photopolymerization Initiator (E)]

The photopolymerization initiator (E) is not particularly limited, and examples thereof include 1-[9-ethyl-6-(2-methylbenzoyl)-9H-carbazol-3-yl-]-, -1-(0-acetyloxime); benzoin and its alkyl ethers such as benzoin, benzoin methyl ether, benzoin ethyl ether, and benzoin butyl ether; acetophenone compounds such as acetophenone, 2,2-dimethoxy-2-phenylacetophenone, 1,1-dichloroacetophenone, and 4′-(1-t-butyldioxy-1-methylethyl)acetophenone; 2-methyl-1-[4-(methylthio)phenyl]-2-morpholino-propane-1-one; 2-benzyl-2-dimethylamino-1-(4-morpholinophenyl)butanone-1; anthraquinone compounds such as 2-methylanthraquinone, 2-amylanthraquinone, 2-t-butylanthraquinone, and 1-chloroanthraquinone; xanthone; thioxanthone compounds such as thioxanthone, 2,4-dimethylthioxanthone, 2,4-diisopropyl thioxanthone, and 2-chlorothioxanthone; ketal compounds such as acetophenone dimethyl ketal and benzyl dimethyl ketal; benzophenone compounds such as benzophenone, 4-(1-t-butyldioxy-1-methylethyl)benzophenone and 3,3′,4,4′-tetrakis(t-butyldioxycarbonyl)benzophenone; and acylphosphine oxide-based photopolymerization initiators. The photopolymerization initiators (E) may be used singly or in combination of two or more kinds thereof.

The content of the photopolymerization initiator (E) in the photosensitive resin composition or photosensitive coloring composition is preferably 0.1 parts by mass or more, more preferably 0.5 parts by mass or more, and still more preferably 1.0 parts by mass or more, with respect to 100 parts by mass of the sum of the modified copolymer (A2), the copolymer (A), and the reactive diluent (D). The content of the photopolymerization initiator (E) in the photosensitive resin composition or photosensitive coloring composition is preferably 30 parts by mass or less, more preferably 15 parts by mass or less, and still more preferably 10 parts by mass or less, with respect to 100 parts by mass of the sum of the modified copolymer (A2), the copolymer (A), and the reactive diluent (D). The combination of these lower and upper limit values may be any combination. When the content of the photopolymerization initiator (E) is 0.1 parts by mass or more, a photosensitive resin composition or photosensitive coloring composition exhibiting favorable photocurability can be obtained. When the content of the photopolymerization initiator (E) is 30 parts by mass or less, it is possible to prevent the physical properties of a cured product of the photosensitive resin composition or photosensitive coloring composition from being adversely affected by an excessive amount of the photopolymerization initiator (E).

### [Coloring Agent (F)]

The photosensitive coloring composition may further contain a coloring agent (F). The photosensitive coloring composition containing the coloring agent (F) can be used as a material for a color filter.

The coloring agent (F) is not particularly limited as long as it is dissolved or dispersed in the solvent (C), and examples thereof include dyes and pigments.

From the viewpoint of solubility in the solvent (C) and the alkaline developer, interaction with other components in the photosensitive coloring composition, heat resistance and the like, it is preferable to use an acidic dye having an acid group such as a carboxy group or a sulfo group, a salt of an acidic dye with a nitrogen compound, a sulfonamide adduct of an acidic dye, and the like as the dye.

Examples of such dyes include acid alizarin violet N; acid black 1, 2, 24, 48; acid blue 1, 7, 9, 25, 29, 40, 45, 62, 70, 74, 80, 83, 90, 92, 112, 113, 120, 129, 147; solvent blue 38, 44, 70; acid chrome violet K; acid Fuchsin; acid green 1, 3, 5, 25, 27, 50; acid orange 6, 7, 8, 10, 12, 50, 51, 52, 56, 63, 74, 95; acid red 1, 4, 8, 14, 17, 18, 26, 27, 29, 31, 34, 35, 37, 42, 44, 50, 51, 52, 57, 69, 73, 80, 87, 88, 91, 92, 94, 97, 103, 111, 114, 129, 133, 134, 138, 143, 145, 150, 151, 158, 176, 183, 198, 211, 215, 216, 217, 249, 252, 257, 260, 266, 274; acid violet 6B, 7, 9, 17, 19; acid yellow 1, 3, 9, 11, 17, 23, 25, 29, 34, 36, 42, 54, 72, 73, 76, 79, 98, 99, 111, 112, 114, 116; food yellow 3 and derivatives thereof. Among these, an azo-based, xanthene-based, anthraquinone-based, or phthalocyanine-based acidic dye is preferable. The dyes may be used singly or in combination of two or more kinds thereof.

Examples of the pigments include yellow pigments such as C.I. pigment yellow 1, 3, 12, 13, 14, 15, 16, 17, 20, 24, 31, 53, 83, 86, 93, 94, 109, 110, 117, 125, 128, 137, 138, 139, 147, 148, 150, 153, 154, 166, 173, 194, 214; orange pigments such as C.I. pigment orange 13, 31, 36, 38, 40, 42, 43, 51, 55, 59, 61, 64, 65, 71, 73; red pigments such as C.I. pigment red 9, 97, 105, 122, 123, 144, 149, 166, 168, 176, 177, 180, 192, 209, 215, 216, 224, 242, 254, 255, 264, 265; blue pigments such as C.I. pigment blue 15, 15: 3, 15: 4, 15: 6, 60; violet pigments such as C.I. pigment violet 1, 19, 23, 29, 32, 36, 38; green pigments such as C.I. pigment green 7, 36, 58, 59; brown pigments such as C.I. pigment brown 23, 25; and black pigments such as C.I. pigment black 1, 7, carbon black, titanium black, and iron oxide. The pigments may be used singly or in combination of two or more kinds thereof.

The coloring agent (F) can be appropriately determined depending on, for example, the color of the desired colored pattern (black matrices and pixels). The coloring agents (F) may be used singly or in combination of two or more kinds thereof. In a case where two or more coloring agents are used as the coloring agent (F), a combination of a dye with a pigment may be used.

In a case where a pigment is used as the coloring agent (F), from the viewpoint of improving pigment dispersibility, a known dispersing agent may be blended into the photosensitive coloring composition. As the dispersing agent, it is preferable to use a polymer dispersing agent excellent in dispersion stability over time. Examples of the polymer dispersing agents include a urethane-based dispersing agent, a polyethyleneimine-based dispersing agent, a polyoxyethylene alkyl ether-based dispersing agent, a polyoxyethylene glycol diester-based dispersing agent, a sorbitan aliphatic ester-based dispersing agent, and an aliphatic modified ester-based dispersing agent. As the polymer dispersing agent, commercially available products under product names such as EFKA (EFKA CHEMICALS B.V.), Disperbyk (BYK), Disparlon (Kusumoto Chemicals, Ltd.), and SOLSPERSE (Lubrizol) may be used. The content of the dispersing agent can be appropriately set depending on the kind and amount of the pigment used as the coloring agent (F).

The content of the coloring agent (F) in the photosensitive coloring composition is preferably 3 parts by mass or more, more preferably 5 parts by mass or more, and still more preferably 10 parts by mass or more, with respect to 100 parts by mass of the sum of the modified copolymer (A2), the copolymer (A), and the reactive diluent (D). The content of the coloring agent (F) in the photosensitive coloring composition is preferably 80 parts by mass or less, more preferably 70 parts by mass or less, and still more preferably 60 parts by mass or less, with respect to 100 parts by mass of the sum of the modified copolymer (A2), the copolymer (A), and the reactive diluent (D). The combination of these lower and upper limit values may be any combination. When the content of the coloring agent (F) is 3 parts by mass or more, the effect obtained by containing the coloring agent (F) becomes significant, and a photosensitive coloring composition suitable as a material for a colored pattern of a color filter can be obtained. When the content of the coloring agent (F) is 80 parts by mass or less, the coloring agent (F) does not interfere with the curability of the photosensitive coloring composition, and a photosensitive coloring composition exhibiting favorable low-temperature curability can be obtained.

### [Other Components]

Into the photosensitive resin composition or photosensitive coloring composition of an embodiment, if necessary, known additives such as a coupling agent, a leveling agent, and a thermal polymerization inhibitor may be blended, in addition to the modified copolymer (A2), the solvent (C), the reactive diluent (D), the photopolymerization initiator (E), and the coloring agent (F) that is contained if necessary. The amount of the additives blended is not particularly limited as long as the effects of the present invention are not impaired.

### <Method for Producing Photosensitive Resin Composition and Photosensitive Coloring Composition>

The photosensitive resin composition according to an embodiment can be produced by a method in which the modified copolymer (A2), the basic catalyst (B), the solvent (C), the reactive diluent (D), the photopolymerization initiator (E), and the optionally used copolymer (A) are mixed together using a known mixing device. The photosensitive coloring composition according to an embodiment can be produced by a method in which the modified copolymer (A2), the basic catalyst (B), the solvent (C), the reactive diluent (D), the photopolymerization initiator (E), the coloring agent (F), and the optionally used copolymer (A) are mixed together using a known mixing device.

When the photosensitive resin composition or photosensitive coloring composition is produced, as a raw material, a reaction liquid (that is, a modified resin composition) containing the modified copolymer (A2) obtained by converting the structural unit (pb) of the copolymer (A) to the structural unit (b), the basic catalyst (B), the solvent (C), and the copolymer (A), which is an optional component, in the resin composition can be used as it is. In this case, the solvent (C) contained in the reaction liquid can be used as part or all of the solvent (C) contained in the photosensitive resin composition or photosensitive coloring composition.

Since the photosensitive resin composition or photosensitive coloring composition contains the modified copolymer (A2) having the structural unit (b) having a group represented by Formula (1-1) or (1-2), the reactive diluent (D), and the photopolymerization initiator (E), the reactive diluent (D) is polymerized together with the ethylenically unsaturated group contained in the structural unit (b) of the modified copolymer (A2) by light irradiation, and favorable photocurability is exerted.

Furthermore, in a case where the photosensitive resin composition or photosensitive coloring composition contains the modified copolymer (A2) containing the structural unit (c) having a hydroxy group and the structural unit (d) having a blocked isocyanate group, the composition exhibits more favorable low-temperature curability.

From these facts, in a case where a cured product is formed using the photosensitive resin composition or photosensitive coloring composition, curing can be performed at a temperature lower than that in the case of using conventional resin compositions. Accordingly, from the photosensitive resin composition or photosensitive coloring composition, a cured product exhibiting excellent solvent resistance can be formed since the crosslinking reaction sufficiently proceeds when the temperature for the baking treatment is lowered as well, for example, in a case where a coating film formed on a base material is exposed and then subjected to a baking treatment.

Therefore, in a case where a cured product is formed using the photosensitive resin composition or photosensitive coloring composition, the energy required for heating to perform curing is small. In addition, by using the photosensitive resin composition or photosensitive coloring composition, a cured product can be formed on a base material exhibiting low heat resistance, such as a resin substrate, without causing any trouble on the base material. Furthermore, from the photosensitive coloring composition, a cured product exerting original properties of the coloring agent (F) can be formed in a case where one exhibiting low heat resistance is used as the coloring agent (F) as well.

Since the photosensitive coloring composition can afford a cured product exhibiting excellent solvent resistance when the temperature for the baking treatment is lowered as well, the coloring agent (F) is hardly eluted. Therefore, it is also possible to increase the content of the coloring agent (F) in the photosensitive coloring composition. A color filter exhibiting excellent color reproducibility can be formed, for example, by using the photosensitive coloring composition having a high content of the coloring agent (F) as a material for a colored pattern of the color filter.

The modified copolymer (A2) contained in the photosensitive resin composition or photosensitive coloring composition has the structural unit (a) having an acid group, and therefore the photosensitive resin composition or photosensitive coloring composition exhibits favorable alkali developability. Since such a photosensitive resin composition or photosensitive coloring composition is excellent in alkali developability, for example, the composition is applied onto a base material to form a coating film, exposure is performed through a photomask corresponding to a predetermined pattern shape, the unexposed portion is developed with an alkaline aqueous solution, a baking treatment is then performed at a sufficiently low temperature, and thus a cured product that is excellent in solvent resistance and has a predetermined pattern shape can be formed.

The photosensitive resin composition and the photosensitive coloring composition can be suitably used as a material for the color filter.

From these facts, the photosensitive resin composition and photosensitive coloring composition are, for example, greatly useful as a material for forming a member of image display elements such as pixels of color filters, black matrices, color filter protective films, photospacers, liquid crystal alignment protrusion, micro lenses, and insulating films for touch panels.

### <Cured Resin Film>

The cured resin film according to an embodiment comprises a cured product of the photosensitive resin composition or photosensitive coloring composition.

The cured resin film can be produced by, for example, a method in which a photosensitive resin composition or photosensitive coloring composition is applied onto a base material, the solvent (C) is removed by volatilization to form a coating film, the coating film is exposed and photocured, and then a baking treatment is performed.

In a case where a cured resin film having a predetermined pattern shape is formed, for example, the following method can be used. Specifically, a photosensitive resin composition or photosensitive coloring composition is applied onto a base material, and the solvent (C) is removed by volatilization to form a coating film. Next, the coating film is exposed through a photomask having a predetermined pattern shape, and the exposed portion is photocured. Next, the unexposed portion of the coating film is developed with an alkaline aqueous solution. Thereafter, the developed coating film is subjected to a baking treatment, and thus a cured resin film having a predetermined pattern shape is formed.

When the cured resin film is produced, known methods can be used as a photosensitive resin composition or photosensitive coloring composition application method, a coating film exposure method, and a development method.

The conditions for the baking treatment performed when the cured resin film is produced can be appropriately determined depending on the formulation of the photosensitive resin composition or photosensitive coloring composition, the film thickness of the coating film, the material for the base material, and the like. The baking treatment can be performed at a temperature of 70° C. to 250° C., for example. When the baking temperature is 70° C. or more, the blocked isocyanate group of the structural unit (d) having a blocked isocyanate group, which is contained in the modified copolymer (A2) in the photosensitive resin composition or photosensitive coloring composition, is sufficiently dissociated. This generates an isocyanate group, which undergoes a crosslinking reaction with the hydroxy group of the structural unit (c) having a hydroxy group. In a case where the structural unit (d) has a carboxylic acid alkyl ester structure, the formation of crosslinking due to transesterification of the carboxylic acid alkyl ester structure with a hydroxy group occurs. As a result, a favorable degree of curing is achieved, and a cured product exhibiting excellent solvent resistance can be obtained. In a case where the structural unit (d) has a carboxylic acid alkyl ester structure, both a deblocking reaction and a transesterification reaction may occur, but one of the reactions can proceed preferentially by adjusting the baking temperature. The temperature for the baking treatment is preferably 75° C. or more, and more preferably 80° C. or more. It is preferable that the temperature for the baking treatment be 250° C. or less since this is a condition under which materials exhibiting low heat resistance can withstand and discoloration of the photosensitive resin composition or photosensitive coloring composition can be suppressed. The photosensitive resin composition and photosensitive coloring composition exhibit favorable low-temperature curability. For this reason, the temperature for the baking treatment can be set to 160° C. or less depending on the heat resistance of the base material on which the cured resin film is formed. For example, in a case where a resin substrate is used as the base material, the temperature for the baking treatment may be set to 150° C. or less, 120° C. or less, or 100° C. or less.

The time for the baking treatment performed when the cured resin film is produced can be, for example, 10 minutes to 4 hours, and preferably 20 minutes to 2 hours, and can be appropriately determined depending on the formulation of the photosensitive resin composition or photosensitive coloring composition, the temperature for the baking treatment, the film thickness of the coating film, and the like.

The cured resin film includes a cured product of the photosensitive resin composition or photosensitive coloring composition. For this reason, the cured resin film can be produced by using a method in which a baking treatment is performed at a low temperature, and further is excellent in solvent resistance.

### <Color Filter>

The color filter of an embodiment has a colored pattern formed of a cured product of the photosensitive coloring composition. The color filter preferably has a colored pattern formed of a cured product of a photosensitive coloring composition containing the modified copolymer (A2) and copolymer (A) at 10 to 90 parts by mass, the basic catalyst (B) at 0.05 to 9 parts by mass, the reactive diluent (D) at 10 to 90 parts by mass, the photopolymerization initiator (E) at 0.1 to 30 parts by mass, the solvent (C) at 30 to 1,000 parts by mass, and the coloring agent (F) at 3 to 80 parts by mass, with respect to 100 parts by mass of the sum of the modified copolymer (A2), the copolymer (A), which is an optional component, and the reactive diluent (D).

The color filter may include, for example, a substrate, RGB pixels formed thereon, black matrices formed at the boundaries between the respective pixels, and protective films formed on the pixels and black matrices.

In the color filter, the pixels and black matrices are colored patterns formed of a cured product of the photosensitive coloring composition. In the color filter, as configuration other than the materials for pixels and black matrices, known configuration can be employed.

The substrate used for the color filter is not particularly limited, and a glass substrate, a silicon substrate, a polycarbonate substrate, a polyester substrate, a polyamide substrate, a polyamideimide substrate, a polyimide substrate, an aluminum substrate, a printed circuit substrate, an array substrate and the like can be appropriately used depending on the application.

### <Method for Producing Color Filter>

Next, an exemplary method for producing a color filter will be described. First, a colored pattern is formed on a substrate. Specifically, on a substrate, a colored pattern to be black matrices formed at the boundaries between the respective pixels and a colored pattern to be the respective RGB pixels are sequentially formed by the following method.

The colored pattern can be formed by photolithography. Specifically, a photosensitive coloring composition is applied onto a substrate to form a coating film. Thereafter, the coating film is exposed through a photomask having a predetermined pattern shape, and the exposed portion is photocured. Next, the unexposed portion of the coating film is developed with an alkaline aqueous solution. Thereafter, the developed coating film is subjected to a baking treatment, and thus a colored pattern having a predetermined pattern shape can be formed.

The method for applying a photosensitive coloring composition is not particularly limited, and known methods such as a screen printing method, a roll coating method, a curtain coating method, a spray coating method, and a spin coating method can be used.

A photosensitive coloring composition may be applied onto a substrate and then, if necessary, the substrate may be heated using a heating unit such as a circulating oven, an infrared heater, or a hot plate to remove the solvent (C) contained in the coating film by volatilization. The conditions for heating the substrate in order to remove the solvent (C) are not particularly limited, and can be appropriately set depending on the material for the substrate, the formulation of the photosensitive coloring composition, the film thickness of the coating film and the like. The substrate can be heated, for example, at a temperature of 50° C. to 120° C. for 30 seconds to 30 minutes.

Next, for example, the coating film thus formed is irradiated with active energy rays such as ultraviolet rays and excimer laser light through a negative type photomask and partially exposed, and the exposed portion is photocured. The quantity of active energy rays emitted to the coating film may be appropriately selected depending on the formulation of the photosensitive coloring composition and the like, and may be, for example, 30 to 2,000 mJ/cm². The light source used for exposure is not particularly limited, and a low-pressure mercury lamp, a medium-pressure mercury lamp, a high-pressure mercury lamp, a xenon lamp, a metal halide lamp or the like can be used.

The alkaline aqueous solution used for developing the coating film is not particularly limited, and for example, aqueous solutions containing an inorganic alkaline compound such as sodium carbonate, potassium carbonate, calcium carbonate, sodium hydroxide, or potassium hydroxide; aqueous solutions containing an amine compound such as ethylamine, diethylamine, or dimethylethanolamine; aqueous solutions containing a quaternary ammonium salt such as a sulfate, hydrochloride or p-toluenesulfonate of tetramethylammonium; aqueous solutions containing an aniline compound such as 3-methyl-4-amino-N,N-diethylaniline, 3-methyl-4-amino-N-ethyl-N-p-hydroxyethylaniline, 3-methyl-4-amino-N-ethyl-N-p-methanesulfonamide ethylaniline, 3-methyl-4-amino-N-ethyl-N-p-methoxyethyl aniline, a sulfate, hydrochloride or p-toluenesulfonate thereof, or a salt thereof; or aqueous solutions containing a p-phenylenediamine compound or a salt thereof can be used. As necessary, additives such as an antifoaming agent and a surfactant may be added to the alkaline aqueous solution.

After the coating film is developed using the alkaline aqueous solution, the coating film is preferably washed with water and dried.

The conditions for the baking treatment performed when the color filter is produced can be appropriately determined depending on the formulation of the photosensitive coloring composition, the film thickness of the coating film, the material for the substrate, and the like. The temperature for the baking treatment may be set to, for example, 70° C. to 210° C. When the baking temperature is 70° C. or more, favorable curability can be obtained, and a cured product exhibiting excellent solvent resistance can be obtained. The temperature for the baking treatment is preferably 75° C. or more, and more preferably 80° C. or more. It is preferable that the temperature for the baking treatment be preferably 210° C. or less since a material exhibiting low heat resistance, such as a substrate exhibiting low heat resistance, can be used as a material for the color filter.

In the case of forming a colored pattern of a color filter using a conventional photosensitive coloring composition, the solvent resistance of the colored pattern is insufficient when the temperature for the baking treatment is set to 200° C. or less. On the other hand, the photosensitive coloring composition of an embodiment exhibits low-temperature curability, and therefore, the temperature for the baking treatment can be lowered compared to the case of using a conventional photosensitive coloring composition while ensuring solvent resistance of the colored pattern. Specifically, the temperature for the baking treatment can be set to 160° C. or less depending on the heat resistance of the base material on which the cured resin film is formed, and may be set to, for example, 150° C. or less, 120° C. or less, or 100° C. or less in a case where a colored pattern is formed using a resin substrate as the base material.

The time for the baking treatment performed when the color filter is produced may be, for example, 10 minutes to 4 hours, and preferably 20 minutes to 2 hours, and can be appropriately determined depending on the formulation of the photosensitive coloring composition, the temperature for the baking treatment, the film thickness of the coating film, and the like.

The photosensitive coloring composition exhibits favorable photocurability and low-temperature curability. For this reason, in a case where a colored pattern is formed using the photosensitive coloring composition of an embodiment, the time for the baking treatment can be shortened, and the color filter can be efficiently formed when the temperature for the baking treatment is set to be equal to that in a case where a colored pattern is formed using a conventional photosensitive coloring composition.

By the method for producing a colored pattern described above, a colored pattern to be the respective RGB pixels and a colored pattern to be black matrices formed at the boundaries between the respective pixels are formed, and a protective film is then formed on the colored patterns (the respective RGB pixels and black matrices).

The method for producing a protective film is not particularly limited, and the protective film may be formed using the photosensitive resin composition of an embodiment, or may be formed using known materials and known methods.

A color filter is obtained by the above steps.

The color filter has a colored pattern formed of a cured product of the photosensitive coloring composition described above. For this reason, the colored pattern in the color filter can be formed by a method in which the baking treatment is performed at a low temperature. Therefore, the energy required for the baking treatment can be decreased.

In addition, as the coloring agent (F) contained in the photosensitive coloring composition used as the material for the color filter, it is possible to use one exhibiting low heat resistance. For this reason, the number of options for usable coloring agents (F) can be increased. Therefore, for example, it is possible to form a color filter that contains the coloring agent (F) exhibiting low heat resistance and has a colored pattern exerting original properties of the coloring agent (F) exhibiting low heat resistance.

Furthermore, the colored pattern in the color filter can be formed on a base material exhibiting low heat resistance, such as a resin substrate, without causing any trouble on the base material. Therefore, the number of options for usable base materials can be increased. Specifically, for example, since a color filter can be formed on a base material exhibiting low heat resistance, such as a resin substrate, the display can be made flexible. In addition, since the colored pattern in the color filter exhibits excellent solvent resistance, color change is small.

Here, a case where a colored pattern is produced using a method in which the photosensitive coloring composition containing the photopolymerization initiator (E) is used and the photosensitive coloring composition is photocured has been exemplified, but a colored pattern formed of a cured product of the photosensitive coloring composition containing the modified copolymer (A2) may be formed, for example, by a method in which a photosensitive coloring composition containing a curing accelerator and a known epoxy resin instead of the photopolymerization initiator (E) contained in the photosensitive coloring composition is used and the composition is applied to a substrate by an inkjet method and then heated.

### <Image Display Element>

An image display element according to an embodiment includes a color filter. In the image display element, as configuration other than the color filter, known configuration can be employed. Specific examples of the image display element include, for example, solid-state imaging devices such as liquid crystal display elements, organic EL display elements, CCD elements and CMOS elements.

Configuration other than the color filter in the image display element can be produced by a known method. For example, in a case where a liquid crystal display element is produced as an image display element, the liquid crystal display element can be produced by the following method. First, a color filter is formed on a substrate by the above-described method. Thereafter, an electrode, a spacer and the like are sequentially formed on the substrate having the color filter. Next, an electrode and the like are formed on another substrate, and this substrate is disposed to face the substrate having the color filter and bonded together. Thereafter, a predetermined amount of liquid crystals is injected between the facing substrates and sealed.

Since the image display element includes the color filter exhibiting excellent solvent resistance, the color change is small.

### EXAMPLES

Hereinafter, the present invention will be described more specifically with reference to Examples and Comparative Examples, but the present invention is not limited to the following Examples.

Synthesis Examples of the modified copolymer (A2) will be described below.

### Example 1 (Synthesis Example 1)

### (Synthesis of Copolymer (A))

In a flask equipped with a stirring device, a dropping funnel, a condenser, a thermometer and a gas inlet tube, 282.6 g of propylene glycol monomethyl ether (Tokyo Chemical Industry Co., Ltd.) as the solvent (C) was added and stirred while performing nitrogen gas purging, and the temperature was raised to 78° C.

Next, 17.2 g (20 mol %) of methacrylic acid as the monomer (m-a), 49.7 g (15 mol %) of 2-[(diethyl malate)carbonylamino]ethyl acrylate as the monomer (m-pb), 19.5 g (15 mol %) of 2-hydroxyethyl methacrylate as the monomer (m-c), 90.3 g (30 mol %) of the reaction product of 2-isocyanatoethyl acrylate with diethyl malonate as the monomer (m-d), 36.8 g (20 mol %) of 2-ethylhexyl acrylate as the monomer (m-e), 64.0 g (30 parts by mass with respect to 100 parts by mass of the sum of the monomer components) of propylene glycol monomethyl ether as the solvent (C), and 34.2 g (16 parts by mass with respect to 100 parts by mass of the sum of the monomer components) of 2,2′-azobis(2,4-dimethylvaleronitrile) (FUJIFILM Wako Pure Chemical Corporation) as a polymerization initiator were mixed together to prepare a raw material monomer solution.

The entire amount of the prepared raw material monomer solution was added dropwise to the solvent (C) in the flask set to be in a nitrogen gas atmosphere at normal pressure using a dropping funnel over 1 hour. After dropwise addition was completed, the solution in the flask was subjected to a polymerization reaction at 78° C. for 3 hours while being stirred to obtain a liquid containing a copolymer (A) and the solvent (C).

### (Preparation of Resin Composition)

To the liquid containing the copolymer (A) and the solvent (C) in the flask set to be in a nitrogen gas atmosphere at normal pressure, 0.4 g (0.2 parts by mass with respect to 100 parts by mass of the sum of monomer components of the copolymer (A)) of hydroquinone monomethyl ether (MEHQ) as a polymerization inhibitor and 10.7 g (5 part by mass with respect to 100 parts by mass of the sum of monomer components of the copolymer (A)) of 4-dimethylaminopyridine (KANTO CHEMICAL CO., INC.) as the basic catalyst (B) were added to obtain a resin composition.

### (Synthesis of Modified Copolymer (A2))

In the flask set to be in a nitrogen gas atmosphere at normal pressure, the resin composition was maintained at 78° C. for 90 minutes while being stirred to convert the structural unit (pb) having a group represented by Formula (1) contained in the copolymer (A) to the structural unit (b) having a group represented by Formula (1-1) or (1-2). Thus, a reaction liquid containing the copolymer (A), a modified copolymer (A2), and the solvent (C) was obtained. The conversion rate from the structural unit (pb) to the structural unit (b) was determined by the above-described methods and is presented in Table 1. The weight average molecular weight, ethylenically unsaturated group equivalent, and acid value of the mixture of the copolymer (A) and modified copolymer (A2) were measured by the above-described methods and are presented in Table 1. The blocked isocyanate group equivalent and hydroxy group equivalent of the mixture of the copolymer (A) and modified copolymer (A2) were calculated and are presented in Table 1.

Propylene glycol monomethyl ether acetate (Tokyo Chemical Industry Co., Ltd.) as the solvent (C) was added to the reaction liquid containing the copolymer (A), the modified copolymer (A2), and the solvent (C), which was thus obtained, so that the components other than the solvent were 35% by mass to obtain a liquid containing the modified copolymer (A2) of Example 1 (modified resin composition).

### Examples 2 to 6 (Synthesis Examples 2 to 6) and Comparative Examples 1 and 2 (Comparative Synthesis Examples 1 and 2)

Liquids containing the modified copolymers (A2) of Examples 2 to 6 (modified resin compositions) and liquids containing the modified copolymers (cA2) of Comparative Examples 1 and 2 (modified resin compositions) were obtained in the same manner as in Example 1 except that the monomers and blended amounts thereof presented in Table 1 were used and the time for the conversion reaction from the structural unit (pb) to the structural unit (b) was set as presented in Table 1. The conversion rate to the structural unit (b) of Examples 2 to 6 was determined by the above-described methods and is presented in Table 1. The weight average molecular weight, ethylenically unsaturated group equivalent, and acid value of the mixtures of the copolymer (A) and modified copolymer (A2) in Examples 2 to 6 and the mixtures of the copolymer (cA) and modified copolymer (cA2) in Comparative Examples 1 and 2 were measured by the above-described methods and are presented in Table 1. The blocked isocyanate group equivalent and hydroxy group equivalent of the mixtures of the copolymer (A) and modified copolymer (A2) in Examples 2 to 6 and the mixtures of the copolymer (cA) and modified copolymer (cA2) in Comparative Examples 1 and 2 were calculated and are presented in Table 1.

### Comparative Example 3 (Comparative Synthesis Example 3)

(Synthesis of Copolymer (cA))

In a flask equipped with a stirring device, a dropping funnel, a condenser, a thermometer and a gas inlet tube, 142.7 g of propylene glycol monomethyl ether acetate (Tokyo Chemical Industry Co., Ltd.) as the solvent (C) was added and stirred while performing nitrogen gas purging, and the temperature was raised to 78° C.

Next, 66.2 g (20 mol %) of 2-[(diethyl malate)carbonylamino]ethyl acrylate as the monomer (m-pb), 39.0 g (30 mol %) of 2-hydroxyethyl methacrylate as the monomer (m-c), 25.1 g (10 mol %) of 2-[(3,5-dimethylpyrazolyl)carbonylamino]ethyl methacrylate as the monomer (m-d), 73.6 g (40 mol %) of 2-ethylhexyl acrylate as the monomer (m-e), and 32.7 g (16 parts by mass with respect to 100 parts by mass of the sum of the monomer components) of 2,2′-azobis(2,4-dimethylvaleronitrile) (FUJIFILM Wako Pure Chemical Corporation) as a polymerization initiator were mixed together to prepare a raw material monomer solution.

The entire amount of the prepared raw material monomer solution was added dropwise to the solvent (C) in the flask set to be in a nitrogen gas atmosphere at normal pressure using a dropping funnel over 1 hour. After dropwise addition was completed, the solution in the flask was subjected to a polymerization reaction at 78° C. for 3 hours while being stirred to obtain a liquid containing a copolymer (cA) and the solvent (C).

### (Preparation of Resin Composition)

To the liquid containing the copolymer (cA) and the solvent (C) in the flask set to be in a nitrogen gas atmosphere at normal pressure, 0.4 g (0.2 parts by mass with respect to 100 parts by mass of the sum of monomer components of the copolymer (cA)) of hydroquinone monomethyl ether (MEHQ) as a polymerization inhibitor and 10.2 g (5 parts by mass with respect to 100 parts by mass of the sum of monomer components of the copolymer (cA)) of 4-dimethylaminopyridine (KANTO CHEMICAL CO., INC.) as a basic catalyst were added to obtain a resin composition.

(Synthesis of Modified Copolymer (cA2))

To the resin composition, 10 g (10 mol with respect to 100 mol of the sum of the monomers used in the synthesis of the copolymer (cA)) of succinic anhydride (SA) (New Japan Chemical Co., Ltd.) and 0.9 g (0.4 parts by mass with respect to 100 parts by mass of the sum of the monomers used in the synthesis of copolymer (cA) and succinic anhydride) of lithium naphthenate (TOEI CHEMICAL INDUSTRY CO., LTD.) as a catalyst were added, and the mixture was maintained at 78° C. for 90 minutes to conduct the addition reaction as well as to convert the structural unit (pb) having a group represented by Formula (1) contained in the copolymer (cA) to the structural unit (b) having a group represented by Formula (1-1) or (1-2). Thus, a reaction liquid containing the copolymer (cA), the modified copolymer (cA2), and the solvent (C) was obtained. The conversion rate from the structural unit (pb) to the structural unit (b) was determined by the above-described methods and is presented in Table 1. The weight average molecular weight, ethylenically unsaturated group equivalent, and acid value of the mixture of the copolymer (cA) and modified copolymer (cA2) were measured by the above-described methods and are presented in Table 1. The blocked isocyanate group equivalent and hydroxy group equivalent of the mixture of the copolymer (cA) and modified copolymer (cA2) were calculated and are presented in Table 1.

Propylene glycol monomethyl ether acetate (Tokyo Chemical Industry Co., Ltd.) as the solvent (C) was added to the reaction liquid containing the copolymer (cA), the modified copolymer (cA2), and the solvent (C), which was thus obtained, so that the components other than the solvent were 35% by mass to obtain a liquid containing the modified copolymer (cA2) of Comparative Example 3 (modified resin composition).

### Comparative Example 4 (Comparative Synthesis Example 4)

In a flask equipped with a stirring device, a dropping funnel, a condenser, a thermometer and a gas inlet tube, 241.2 g of propylene glycol monomethyl ether (Tokyo Chemical Industry Co., Ltd.) as the solvent (C) was added and stirred while performing nitrogen gas purging, and the temperature was raised to 78° C.

Next, 15.5 g (18 mol %) of methacrylic acid as the monomer (m-a), 18.2 g (14 mol %) of 2-hydroxyethyl methacrylate as the monomer (m-c), 60.2 g (20 mol %) of the reaction product of 2-isocyanatoethyl acrylate with diethyl malonate as the monomer (m-d), 88.3 g (48 mol %) of 2-ethylhexyl acrylate as the monomer (m-e), 54.7 g (30 parts by mass with respect to 100 parts by mass of the sum of the monomer components) of propylene glycol monomethyl ether as the solvent (C), and 29.2 g (16 parts by mass with respect to 100 parts by mass of the sum of the monomer components) of 2,2′-azobis(2,4-dimethylvaleronitrile) (FUJIFILM Wako Pure Chemical Corporation) as a polymerization initiator were mixed together to prepare a raw material monomer solution.

The entire amount of the prepared raw material monomer solution was added dropwise to the solvent (C) in the flask set to be in a nitrogen gas atmosphere at normal pressure using a dropping funnel over 1 hour. After dropwise addition was completed, the solution in the flask was subjected to a polymerization reaction at 78° C. for 3 hours while being stirred to obtain a reaction liquid containing a copolymer (cA) and the solvent (C). The weight average molecular weight, ethylenically unsaturated group equivalent, and acid value of the copolymer (cA) were measured by the above-described methods and are presented in Table 1. The blocked isocyanate group equivalent and hydroxy group equivalent of the copolymer (cA) were calculated and are presented in Table 1.

Propylene glycol monomethyl ether acetate (Tokyo Chemical Industry Co., Ltd.) as the solvent (C) was added to the reaction liquid containing the copolymer (cA) and the solvent (C), which was thus obtained, so that the components other than the solvent were 35% by mass to obtain a liquid containing the copolymer (cA) of Comparative Example 4 (resin composition).

### [Table 1-1]

TABLE 1

| | | | | | | Ex. 1 | Ex. 2 | Ex. 3 | Ex. 4 | Ex. 5 | Ex. 6 |
|---|---|---|---|---|---|---|---|---|---|---|---|
| | | | | | | Syn. | Syn. | Syn. | Syn. | Syn. | Syn. |
| | | | | pKa | Unit | Ex. 1 | Ex. 2 | Ex. 3 | Ex. 4 | Ex. 5 | Ex. 6 |
| Copolymer | Monomer | m-a | MAA | — | mol % | 20 | 20 | 20 | 20 | 20 | 20 |
| | | m-pb | AOI-MDE | — | | 15 | 20 | 15 | 15 | 15 | 15 |
| | | m-c | HEMA | — | | 15 | 20 | 15 | 15 | 15 | 15 |
| | | m-d | AOI-DEM | — | | 30 | — | 30 | 30 | 30 | 30 |
| | | | MOI-BP | — | | — | 20 | — | — | — | — |
| | | m- e | 2EHA | — | | 20 | 20 | 20 | 20 | 20 | 20 |

| Sum | | | | 100 | 100 | 100 | 100 | 100 | 100 |
|---|---|---|---|---|---|---|---|---|---|
| Addition reaction | SA | — | mol *¹ | — | — | — | — | — | — |

| Polymerization inhibitor | MEHQ | — | Parts by | 0.2 | 0.2 | 0.2 | 0.2 | 0.2 | 0.2 |
|---|---|---|---|---|---|---|---|---|---|
| | | | mass*² | | | | | | |
| Basic catalyst | DBU | 12.5 | Parts by | — | — | — | — | — | — |
| | DMAP | 9.7 | mass*² | 5 | 5 | — | — | — | — |
| | Pyridine | 5.2 | | — | — | 5 | — | — | — |
| | 1,2-Dimethylimidazole | 7.8 | | — | — | — | 5 | — | — |
| | Triethylamine | 10.7 | | — | — | — | — | 5 | — |
| | DABCO | 8.8 | | — | — | — | — | — | 5 |

| | | | | | | | |
|---|---|---|---|---|---|---|---|
| Conversion reaction time | Minutes | 90 | 90 | 90 | 90 | 90 | 90 |
| Weight average molecular weight | | 6200 | 6300 | 7400 | 7100 | 7600 | 7700 |
| Ethylenically unsaturated group equivalent | g/mol | 2013 | 1702 | 4026 | 2464 | 2144 | 2063 |
| Conversion rate | % | 82 | 67 | 41 | 67 | 77 | 80 |
| Acid value | KOHmg/g | 61.7 | 70.5 | 61.7 | 61.7 | 61.7 | 61.7 |
| Blocked isocyanate group equivalent | g/mol | 413 | 1140 | 413 | 413 | 413 | 413 |
| Hydroxy group equivalent | g/mol | 1651 | 1140 | 1651 | 1651 | 1651 | 1651 |
| Storage stability | | 12% | 16% | 8% | 11% | 13% | 15% |

*¹ Number of moles with respect to 100 mol of sum of monomers
*²Parts by mass with respect to 100 parts by mass of sum of monomers

TABLE 1-2
(Continued from Table 1)

| | | | | | | Comp. | Comp. | Comp. | Comp. |
|---|---|---|---|---|---|---|---|---|---|
| | | | | | | Ex. 1 | Ex. 2 | Ex. 3 | Ex. 4 |
| | | | | | | Comp. Syn. | Comp. Syn. | Comp. Syn. | Comp. Syn. |
| | | | | pKa | [symbol] | Ex. 1 | Ex. 2 | Ex. 3 | Ex. 4 |
| Copolymer | Monomer | m-a | MAA | — | mol % | 20 | 20 | — | 18 |
| | | m-pb | AOI-MDE | — | | 15 | 15 | 20 | — |
| | | m-c | HEMA | — | | 15 | 15 | 30 | 14 |
| | | m-d | AOI-DEM | — | | 30 | 30 | — | 20 |
| | | | MOI-BP | — | | — | — | 10 | — |
| | | m- e | 2EHA | — | | 20 | 20 | 40 | 48 |

| Sum | | | | 100 | 100 | 100 | 100 |
|---|---|---|---|---|---|---|---|
| Addition reaction | SA | — | mol *¹ | — | — | 10 | — |

| Polymerization inhibitor | MEHQ | — | Parts by | 0.2 | 0.2 | 0.2 | — |
|---|---|---|---|---|---|---|---|
| | | | mass*² | | | | |
| Basic catalyst | DBU | 12.5 | Parts by | 1 | 5 | — | — |
| | DMAP | 9.7 | mass*² | — | — | 5 | — |
| | Pyridine | 5.2 | | — | — | — | — |
| | 1,2-Dimethylimidazole | 7.8 | | — | — | — | — |
| | Triethylamine | 10.7 | | — | — | — | — |
| | DABCO | 8.8 | | — | — | — | — |

| | | | | | |
|---|---|---|---|---|---|
| Conversion reaction time | Minutes | 180 | 90 | 90 | — |
| Weight average molecular weight | | 6800 | 10500 | 11400 | 6700 |
| Ethylenically unsaturated group equivalent | g/mol | 7503 | 6114 | 1233 | 0 |
| Conversion rate | % | 22 | 27 | 54 | — |
| Acid value | KOHmg/g | 62.5 | 61.7 | 35.1 | 55.7 |
| Blocked isocyanate group equivalent | g/mol | 413 | 413 | 2465 | 528 |
| Hydroxy group equivalent | g/mol | 1651 | 1651 | 1233 | 1510 |
| Storage stability | | 22% | 35% | 18% | 1% |

*¹ Number of moles with respect to 100 mol of sum of monomers
*²Parts by mass with respect to 100 parts by mass of sum of monomers

As the compounds described in Tables 1 and 2, the following compounds were used, respectively.
MAA: Methacrylic acid (Kuraray Co., Ltd.)
AOI-MDE: Karenz (trademark) AOI-MDE, 2-[(diethyl malate)carbonylamino]ethyl acrylate (Resonac Corporation)
AOI-DEM: Karenz (trademark) AOI-DEM, reaction product of 2-isocyanatoethyl acrylate with diethyl malonate (malonic acid-2-[[[1-oxo-2-propenyl]oxy]ethyl]amino]carbonyl]-1,3 diethyl ester, Resonac Corporation)
MOI-BP: Karenz (trademark) MOI-BP, 2-[(3,5-dimethylpyrazolyl)carbonylamino]ethyl methacrylate (Resonac Corporation)
HEMA: 2-Hydroxyethyl methacrylate (Nippon Shokubai Co., Ltd.)
2EHA: 2-Ethylhexyl acrylate (Toagosei Company, Limited)
SA: Succinic anhydride (New Japan Chemical Co., Ltd.)
DBU: 1,8-Diazabicyclo[5.4.0]-7-undecene (San-Apro Ltd.)
DMAP: 4-Dimethylaminopyridine (KANTO CHEMICAL CO., INC.)
Pyridine (KANTO CHEMICAL CO., INC.)
1,2-Dimethylimidazole (Tokyo Chemical Industry Co., Ltd.)
Triethylamine (KANTO CHEMICAL CO., INC.)
DABCO: 1,4-Diazabicyclo[2.2.2]octane (KANTO CHEMICAL CO., INC.)

### [Evaluation of Storage Stability]

In a 20 mL sample bottle, 10 mL of the modified resin composition obtained in Example 1 was measured and placed, and the sample bottle was sealed and stored at 5° C. for 3 months. The weight average molecular weight of the sample after storage was measured, and the rate of increase in weight average molecular weight was calculated according to the following equation. The rate of increase in weight average molecular weight of the modified resin compositions obtained in Examples 2 to 6 and Comparative Examples 1 to 3 and the resin composition obtained in Comparative Example 4 was also calculated in the same manner. The rate of increase in weight average molecular weight is presented in Table 1. When the rate of increase is within 20%, storage stability is favorable.

$$Rate of increase in weight average molecular weight ( \% ) = [ ( weight average molecular weight after storage - weight average molecular weight before storage ) / weight average molecular weight before storage ] \times 100$$

### Examples 7 to 12 and Comparative Examples 5 to 8

Using the modified resin compositions of Examples 1 to 6 and Comparative Examples 1 to 3 and the resin composition of Comparative Example 4, mixtures of the copolymers (A) and modified copolymers (A2) of Synthesis Examples 1 to 6 or mixtures of the copolymer (cA) and modified copolymer (cA2) of Comparative Synthesis Examples 1 to 3 or the copolymer (cA) of Comparative Synthesis Example 4, a basic catalyst, dipentaerythritol pentaacrylate (Toagosei Company, Limited) as the reactive diluent (D), 1-[9-ethyl-6-(2-methylbenzoyl)-9H-carbazol-3-yl]-, -1-(O-acetyloxime) (Ciba Japan Co., Ltd.) as the photopolymerization initiator (E), a mixture of propylene glycol monomethyl ether acetate and propylene glycol monomethyl ether (338 parts by mass and 257 parts by mass, respectively) as the solvent (C), and Valifast Blue 2620 (phthalocyanine dye, ORIENT CHEMICAL INDUSTRIES CO., LTD.) as the coloring agent (F) presented in Table 2 were each mixed together in the proportions presented in Table 2, thereby preparing the photosensitive coloring compositions of Examples 7 to 12 and Comparative Examples 5 to 8, respectively.

The blended amount of the mixture of the copolymer (A) and modified copolymer (A2) or the mixture of the copolymer (cA) and modified copolymer (cA2) or the copolymer (cA) presented in Table 2 does not include the amount of solvent. The blended amount of the solvent (C) presented in Table 2 is the summed value of the amount of solvent contained in the modified resin compositions or resin compositions obtained in Synthesis Examples 1 to 6 and Comparative Synthesis Examples 1 to 4 and the amount of solvent added during preparation of the photosensitive coloring composition.

TABLE 2

| | | | Ex. 7 | Ex. 8 | Ex. 9 | Ex. 10 | Ex. 11 | Ex. 12 |
|---|---|---|---|---|---|---|---|---|
| Mixture of | Syn. Ex. 1 | Parts by mass | 100 | — | — | — | — | — |
| modified | Syn. Ex. 2 | | — | 100 | — | — | — | — |
| copolymer (A2) | Syn. Ex. 3 | | — | — | 100 | — | — | — |
| and copolymer | Syn. Ex. 4 | | — | — | — | 100 | — | — |
| (A) or mixture | Syn. Ex. 5 | | — | — | — | — | 100 | — |
| of modified | Syn. Ex. 6 | | — | — | — | — | — | 100 |
| copolymer | Comp. Syn. Ex. 1 | | — | — | — | — | — | — |
| (cA2) and | Comp. Syn. Ex. 2 | | — | — | — | — | — | — |
| copolymer (cA) | Comp. Syn. Ex. 3 | | — | — | — | — | — | — |
| Copolymer (cA) | Comp. Syn. Ex. 4 | | — | — | — | — | — | — |
| Basic catalyst | DBU | | — | — | — | — | — | — |
| | DMAP | | 5 | 5 | — | — | — | — |
| | Pyridine | | — | — | 5 | — | — | — |
| | 1,2-Dimethylimidazole | | — | — | — | 5 | — | — |
| | Triethylamine | | — | — | — | — | 5 | — |
| | DABCO | | — | — | — | — | — | 5 |

| | | | | | | | |
|---|---|---|---|---|---|---|---|
| Reactive diluent (D) | | 100 | 100 | 100 | 100 | 100 | 100 |
| Photopolymerization initiator (E) | | 5 | 5 | 5 | 5 | 5 | 5 |
| Soevent (C) | | 595 | 595 | 595 | 595 | 595 | 595 |
| Coloring agent (F) | | 50 | 50 | 50 | 50 | 50 | 50 |
| Solvent resistance (100° C. 20 min) | Residual film | 90 | 92 | 85 | 90 | 89 | 91 |
| | rate(%) | | | | | | |
| Developability | Solubility | 1 | 2 | 1 | 1 | 1 | 1 |
| | Adhesive | 5 | 10 | 5 | 7 | 6 | 8 |
| | properties | | | | | | |
| | (μm) | | | | | | |

TABLE 2-2
(Continued from Table 2)

| | | | Comp. | Comp. | Comp. | Comp. |
|---|---|---|---|---|---|---|
| | | | Ex. 5 | Ex. 6 | Ex. 7 | Ex. 8 |
| Mixture of | Syn. Ex. 1 | Parts by mass | — | — | — | — |
| modified | Syn. Ex. 2 | | — | — | — | — |
| copolymer (A2) | Syn. Ex. 3 | | — | — | — | — |
| and copolymer | Syn. Ex. 4 | | — | — | — | — |
| (A) or mixture | Syn. Ex. 5 | | — | — | — | — |
| of modified | Syn. Ex. 6 | | — | — | — | — |
| copolymer | Comp. Syn. Ex. 1 | | 100 | — | — | — |
| (cA2) and | Comp. Syn. Ex. 2 | | — | 100 | — | — |
| copolymer (cA) | Comp. Syn. Ex. 3 | | — | — | 100 | — |
| Copolymer (cA) | Comp. Syn. Ex. 4 | | — | — | — | 100 |
| Basic catalyst | DBU | | 1 | 5 | — | — |
| | DMAP | | — | — | 5 | — |
| | Pyridine | | — | — | — | — |
| | 1,2-Dimethylimidazole | | — | — | — | — |
| | Triethylamine | | — | — | — | — |
| | DABCO | | — | — | — | — |

| | | | | | |
|---|---|---|---|---|---|
| Reactive diluent (D) | | 100 | 100 | 100 | 100 |
| Photopolymerization initiator (E) | | 5 | 5 | 5 | 5 |
| Soevent (C) | | 595 | 595 | 595 | 595 |
| Coloring agent (F) | | 50 | 50 | 50 | 50 |
| Solvent resistance (100° C. 20 min) | Residual film | 81 | 83 | 91 | 85 |
| | rate(%) | | | | |
| Developability | Solubility | 1 | 1 | 3 | 3 |
| | Adhesive | 7 | 6 | 16 | 30 |
| | properties | | | | |
| | (μm) | | | | |

### [Evaluation of Solvent Resistance]

The solvent resistance was evaluated on the basis of the residual film rate.

### (Residual Film Rate)

Each of the photosensitive coloring compositions of Examples 7 to 12 and Comparative Examples 5 to 8 was applied onto a glass substrate (alkali-free glass substrate) having a square shape of 5 cm in length and 5 cm in width in plan view by a spin coating method so that the thickness after exposure was 2.5 μm to form a coating film. Next, heating was performed at 100° C. for 3 minutes to remove the solvent (C) in the coating film by volatilization.

Next, the coating film was irradiated with ultraviolet rays having a wavelength of 365 nm in a quantity of energy of 100 mJ/cm² for exposure, and the exposed portion was photocured. Thereafter, the coating film was cured by performing a baking treatment at 100° C. for 20 minutes to obtain a cured film. The thickness of the cured film thus fabricated was measured with a step gauge. The thickness at this time was denoted as X.

Thereafter, the fabricated cured film was immersed in 20 g of propylene glycol monomethyl ether acetate (PGMEA) at 23° C. for 15 minutes. After immersion, the coating film was vacuum dried at 40° C. for 30 minutes, and the thickness of the coating film was then measured with a step gauge. The thickness at this time was denoted as Y.

The proportion of the thickness Y of the cured film after immersion in PGMEA to the thickness X of the cured film before immersion in PGMEA was calculated as the residual film rate by the following equation to evaluate the solvent resistance of the cured film. Specifically, the solvent resistance of the cured film is more favorable as the residual film rate is closer to 100%. As the evaluation, 80% or more of the residual film rate was determined as a pass line. The residual film rate of the cured film is presented in Table 2.

$$Residual film rate = ( Y / X ) \times 100 ( \% )$$

As presented in Table 2, the cured films of the resin compositions of Examples 7 to 12 had a residual film rate (%) of 85% or more after immersion in PGMEA and exhibited favorable solvent resistance when the temperature for the baking treatment was as low as 100° C.

### [Evaluation of Developability]

The developability was evaluated on the basis of the solubility and adhesive properties of the cured film.

### (Solubility)

Each of the photosensitive coloring compositions of Examples 7 to 12 and Comparative Examples 5 to 8 was applied onto a 5 cm square glass substrate (alkali-free glass substrate) by a spin coating method so that the thickness after exposure was 1.5 μm (application step). The glass substrate coated with the photosensitive coloring composition was heated at 100° C. for 3 minutes to volatilize the solvent and dry the coating film (pre-baking step).

Next, the surface of the dried coating film was irradiated with light of 100 mJ/cm² using an ultra-high pressure mercury lamp through a photomask (exposure step). The exposure step was carried out with placing the photomask at a position 100 m away from the coating film. As the photomask, a mask having a line and space pattern with a width of 3 to 100 m was used. Next, Semi-clean DL-A10 developer (YOKOHAMA OILS & FATS INDUSTRY CO., LTD.) (diluted by 300-fold) was sprayed onto the surface of the coating film for 60 seconds at a temperature of 23° C. and a pressure of 0.1 MPa to remove the unexposed portions (development step). The dissolved form of the coating film when sprayed with the developer was observed, and the solubility was evaluated according to the following criteria. The results are presented in Table 2.
1: No residue remains in the unexposed portions, no powder is found in the developer, and the pattern shape is favorable
2: No residue remains in the unexposed portions, powder is found in the developer, and the pattern shape is relatively favorable
3: Residues remain in the unexposed portions and there are places where the pattern shape is missing
4: The film is peeled off in the exposed portion, and no pattern remains

### (Adhesive Properties)

The glass substrate having the coating film after the development step was allowed to stand in a drier at 100° C. for 30 minutes to thermally cure the coating film (post-baking step) to obtain a colored pattern. The colored pattern thus obtained was observed using a microscope, and the adhesive properties were evaluated on the basis of the minimum line width developed (minimum development dimension (μm)). The results are presented in Table 2.

### INDUSTRIAL APPLICABILITY

According to the present disclosure, there is provided a photosensitive resin composition that contributes to improvement in developability and affords a cured resin film exhibiting excellent solvent resistance. According to the present disclosure, there is provided an image display element that includes a color filter having a colored pattern formed of a cured resin film excellent in solvent resistance. The photosensitive resin composition and the photosensitive coloring composition can be preferably used as materials for a transparent film, a protective film, an insulating film, an overcoat, a photospacer, a black matrix, a black column spacer, a resist for color filters, and the like.

1: A resin composition comprising: a copolymer (A);
a basic catalyst (B); and
a solvent (C),
wherein
the copolymer (A) is a copolymer comprising:
a structural unit (a) having an acid group; and
a structural unit (pb) having a group represented by the following Formula (1),
and
the basic catalyst (B) is a basic catalyst having a pKa (acidity constant) of 4 to 12 at 25° C.; 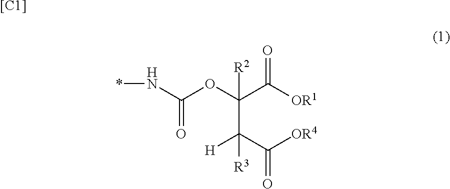
(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)).

2: A modified resin composition comprising: a modified copolymer (A2);
a basic catalyst (B); and
a solvent (C),
wherein
the modified copolymer (A2) comprises:
a structural unit (a) having an acid group;
a structural unit (pb) having a group represented by the following Formula (1); and
a structural unit (b) having a group represented by the following Formula (1-1) or (1-2), and
the basic catalyst (B) is a basic catalyst having a pKa (acidity constant) of 4 to 12 at 25° C.; 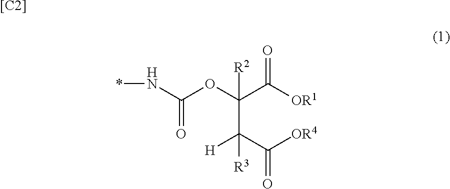
(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)), 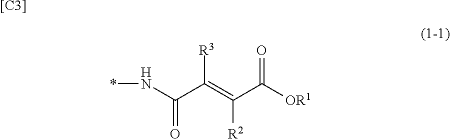
(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b)), and 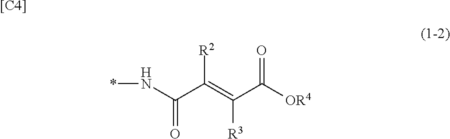
(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b)).

3: The modified resin composition according to claim 2, wherein the basic catalyst (B) is at least one selected from the group consisting of pyridine, a pyridine derivative, and an imidazole compound.

4: The modified resin composition according to claim 2, wherein the basic catalyst (B) is at least one selected from pyridine, 4-dimethylaminopyridine, 1,2-dimethylimidazole, triethylamine, and 1,4-diazabicyclo[2.2.2]octane.

5: The modified resin composition according to claim 2, wherein the modified copolymer (A2) has an ethylenically unsaturated group equivalent of 300 to 10,000 g/mol.

6: A photosensitive resin composition comprising: the modified resin composition according to claim 2;
a reactive diluent (D); and
a photopolymerization initiator (E).

7: A photosensitive coloring composition comprising: the modified resin composition according to claim 2;
a reactive diluent (D);
a photopolymerization initiator (E); and
a coloring agent (F).

8: A cured resin film comprising a cured product of the photosensitive resin composition according to claim 6.

9: A cured resin film comprising a cured product of the photosensitive coloring composition according to claim 7.

10: A color filter comprising a colored pattern comprising a cured product of the photosensitive coloring composition according to claim 7.

11: An image display element comprising the color filter according to claim 10.

12: A method for producing a resin composition, the method comprising: a step (I) of preparing the resin composition comprising a copolymer (A), a basic catalyst (B), and a solvent (C), wherein
the copolymer (A) is a copolymer comprising:
a structural unit (a) having an acid group; and
a structural unit (pb) having a group represented by the following Formula (1),
and
the basic catalyst (B) is a basic catalyst having a pKa (acidity constant) of 4 to 12 at 25° C.; 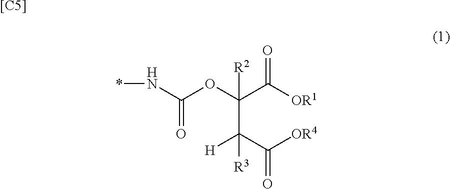
(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)).

13: A method for producing a modified resin composition, the method comprising: a heating step (II) of maintaining the resin composition obtained by the production method according to claim 12 at 50° C. to 100° C. for 30 to 300 minutes, wherein
in the heating step (II), the copolymer (A) is converted to a modified copolymer (A2),
the modified copolymer (A2) comprises:
a structural unit (a) having an acid group;
a structural unit (pb) having a group represented by the following Formula (1); and
a structural unit (b) having a group represented by the following Formula (1-1) or (1-2): 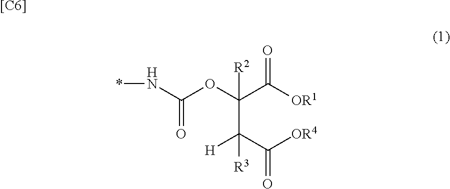
(in Formula (1), R¹ and R⁴ are each independently a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1) from the structural unit (pb)), 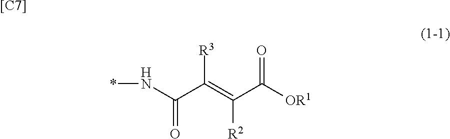
(in Formula (1-1), R¹ is a hydrogen atom or a hydrocarbon group having 1 to 20 carbon atoms, R² and R³ are each independently a hydrogen atom or a hydrocarbon group having 1 to 20 carbon atoms, and * represents a linking site with a residue obtained by removing the group represented by Formula (1-1) from the structural unit (b)), and 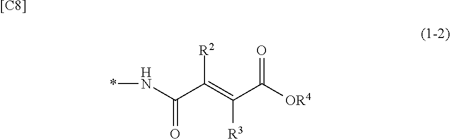
(in Formula (1-2), R² and R³ are each independently a hydrogen atom or a hydrocarbon group having 1 to 20 carbon atoms, R⁴ is a hydrogen atom or a hydrocarbon group having 1 to 20 carbon atoms, and * represents a linking site with a residue obtained by removing the group represented by Formula (1-2) from the structural unit (b)).
